(19) United States
(12) Patent Application Publication
(10) Pub. No.: US 2025/0298944 A1
(43) Pub. Date: Sep. 25, 2025

(54) DRILLING OPERATIONS FRAMEWORK

(71) Applicant: Schlumberger Technology Corporation, Sugar Land, TX (US)

(72) Inventors: Agustin Soriano Rementeria, Montpellier (FR); Myriam Amour, Montpellier (FR)

(21) Appl. No.: 19/085,502

(22) Filed: Mar. 20, 2025

Related U.S. Application Data
(60) Provisional application No. 63/568,455, filed on Mar. 22, 2024.

(51) Int. Cl. G06F 30/27

(52) U.S. Cl. CPC G06F 30/27

(57) ABSTRACT

A method may include receiving a prompt by a generative artificial intelligence engine, where the prompt describes a drilling analysis; responsive to the prompt, generating configuration settings for one or more graphical user interfaces of one or more computational frameworks; and transmitting instructions for rendering at least one of the graphical user interfaces to a display according to its configuration settings.

### RELATED APPLICATION

This application claims priority to and the benefit of a U.S. Provisional Application having Ser. No. 63/568,455, filed 22 Mar. 2024, which is incorporated by reference herein in its entirety.

### BACKGROUND

A reservoir may be a subsurface formation that may be characterized at least in part by its porosity and fluid permeability. As an example, a reservoir may be part of a basin such as a sedimentary basin. A basin may be a depression (e.g., caused by plate tectonic activity, subsidence, etc.) in which sediments accumulate. As an example, where hydrocarbon source rocks occur in combination with appropriate depth and duration of burial, a petroleum system may develop within a basin, which may form a reservoir that includes hydrocarbon fluids (e.g., oil, gas, etc.).

In oil and gas exploration, interpretation is a process that involves analysis of data to identify and locate various subsurface structures (e.g., horizons, faults, geobodies, etc.) in a geologic environment. Various types of structures (e.g., stratigraphic formations) may be indicative of hydrocarbon traps or flow channels, as may be associated with one or more reservoirs (e.g., fluid reservoirs). In the field of resource extraction, enhancements to interpretation may allow for construction of a more accurate model of a subsurface region, which, in turn, may improve characterization of the subsurface region for purposes of resource extraction. Characterization of one or more subsurface regions in a geologic environment may guide, for example, performance of one or more operations (e.g., field operations, etc.). As an example, a plan may depend on a model of a subsurface region where the plan may specify how a drilling operation may accurately construct a borehole according to a trajectory that penetrates a reservoir, etc., where fluid may be produced via the borehole (e.g., as a completed well, etc.). As an example, one or more workflows may be performed using one or more computational frameworks, systems, etc., for one or more of analysis, acquisition, model building, control, etc., for exploration, interpretation, drilling, fracturing, production, etc.

### SUMMARY

A method may include receiving a prompt by a generative artificial intelligence engine, where the prompt describes a drilling analysis; responsive to the prompt, generating configuration settings for one or more graphical user interfaces of one or more computational frameworks; and transmitting instructions for rendering at least one of the graphical user interfaces to a display according to its configuration settings. A system may include one or more processors; memory accessible to at least one of the one or more processors; processor-executable instructions stored in the memory and executable to instruct the system to: receive a prompt by a generative artificial intelligence engine, where the prompt describes a drilling analysis; responsive to the prompt, generate configuration settings for one or more graphical user interfaces of one or more computational frameworks; and transmit instructions for rendering at least one of the graphical user interfaces to a display according to its configuration settings. One or more computer-readable storage media may include processor-executable instructions to instruct a computing system to: receive a prompt by a generative artificial intelligence engine, where the prompt describes a drilling analysis; responsive to the prompt, generate configuration settings for one or more graphical user interfaces of one or more computational frameworks; and transmit instructions for rendering at least one of the graphical user interfaces to a display according to its configuration settings. Various other apparatuses, systems, methods, etc., are also disclosed.

This summary is provided to introduce a selection of concepts that are further described below in the detailed description. This summary is not intended to identify key or essential features of the claimed subject matter, nor is it intended to be used as an aid in limiting the scope of the claimed subject matter.

### BRIEF DESCRIPTION OF THE DRAWINGS

The following detailed description refers to the accompanying drawings. Wherever convenient Features and advantages of the described implementations may be more readily understood by reference to the following description taken in conjunction with the accompanying drawings.

FIG. 1 shows an example of a system;

FIG. 2 shows an example of a system;

FIG. 3 shows an example of a system;

FIG. 4 shows an example of a system;

FIG. 5 shows a series of example graphical user interfaces of an example of a workflow;

FIG. 6 shows an example of a graphical user interface;

FIG. 7 shows examples of architectures;

FIG. 8 shows an example of a graphical user interface;

FIG. 9 shows an example of a method;

FIG. 10 shows an example of a method;

FIG. 11 shows an example of a graphical user interface;

FIG. 12 shows an example of a graphical user interface;

FIG. 13 shows an example of a graphical user interface;

FIG. 14 shows an example of a graphical user interface;

FIG. 15 shows an example of a method and an example of a system; and

FIG. 16 shows an example of a system.

### DETAILED DESCRIPTION

This description is not to be taken in a limiting sense, but rather is made merely for the purpose of describing the general principles of the implementations. The scope of the described implementations should be ascertained with reference to the issued claims.

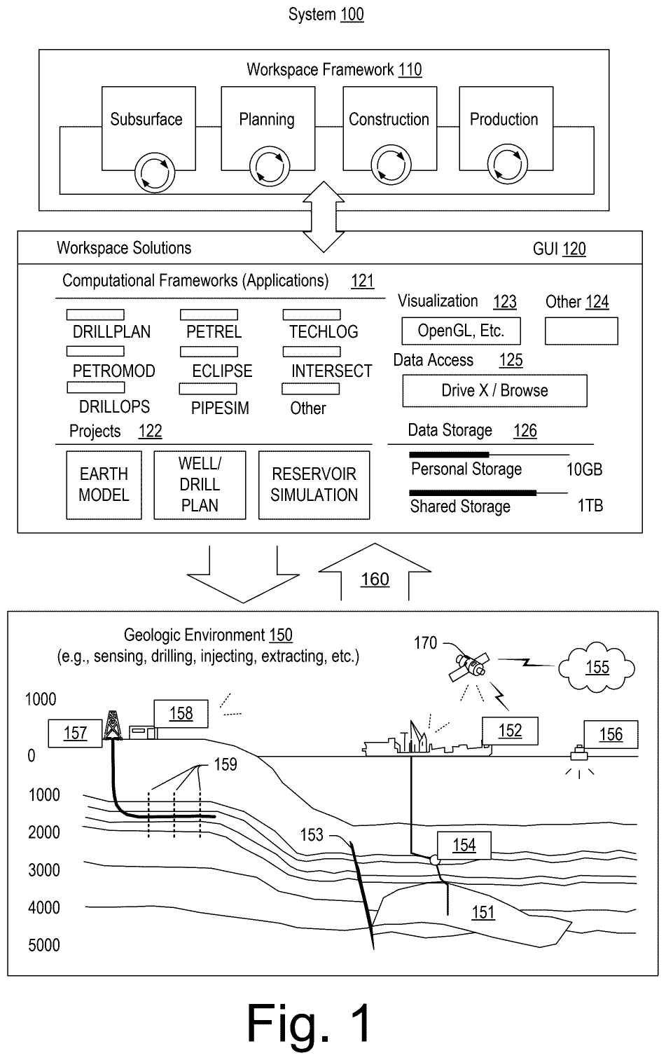

FIG. 1 shows an example of a system 100 that includes a workspace framework 110 that may provide for instantiation of, rendering of, interactions with, etc., a graphical user interface (GUI) 120. In the example of FIG. 1, the GUI 120 may include graphical controls for computational frameworks (e.g., applications, etc.) 121, projects 122, visualization features 123, one or more other features 124, data access 125, and data storage 126.

In the example of FIG. 1, the workspace framework 110 may be tailored to a particular geologic environment such as an example geologic environment 150. For example, the geologic environment 150 may include layers (e.g., stratification) that include a reservoir 151 and that may be intersected by a fault 153. As an example, the geologic environment 150 may be outfitted with a variety of sensors, detectors, actuators, etc. For example, equipment 152 may include communication circuitry to receive and to transmit information with respect to one or more networks 155. Such information may include information associated with downhole equipment 154, which may be equipment to acquire information, to assist with resource recovery, etc. Other equipment 156 may be located remote from a wellsite and include sensing, detecting, emitting or other circuitry. Such equipment may include storage and communication circuitry to store and to communicate data, instructions, etc. As an example, one or more satellites may be provided for purposes of communications, data acquisition, etc. For example, FIG. 1 shows a satellite 170 in communication with the network 155 that may be configured for communications, noting that the satellite 170 may additionally or alternatively include circuitry for imagery (e.g., spatial, spectral, temporal, radiometric, etc.).

FIG. 1 also shows the geologic environment 150 as optionally including equipment 157 and 158 associated with a well that includes a substantially horizontal portion that may intersect with one or more fractures 159. For example, consider a well in a shale formation that may include natural fractures, artificial fractures (e.g., hydraulic fractures) or a combination of natural and artificial fractures. As an example, a well may be drilled for a reservoir that is laterally extensive. In such an example, lateral variations in properties, stresses, etc. may exist where an assessment of such variations may assist with planning, operations, etc. to develop a laterally extensive reservoir (e.g., via fracturing, injecting, extracting, etc.). As an example, the equipment 157 and/or 158 may include components, a system, systems, etc. for fracturing, seismic sensing, analysis of seismic data, assessment of one or more fractures, etc.

In the example of FIG. 1, the GUI 120 shows some examples of computational frameworks, including the DRILLPLAN, DRILLOPS, PETREL, TECHLOG, PETROMOD, ECLIPSE, PIPESIM, and INTERSECT frameworks (SLB, Houston, Texas).

The DRILLPLAN framework provides for digital well construction planning and includes features for automation of repetitive tasks and validation workflows, enabling improved quality drilling programs (e.g., digital drilling plans, etc.) to be produced quickly with assured coherency.

The DRILLOPS framework may execute a digital drilling plan and ensures plan adherence, while delivering goal-based automation. The DRILLOPS framework may generate activity plans automatically individual operations, whether they are monitored and/or controlled on the rig or in town. Automation may utilize data analysis and learning systems to assist and optimize tasks, such as, for example, setting ROP to drilling a stand. A preset menu of automatable drilling tasks may be rendered, and, using data analysis and models, a plan may be executed in a manner to achieve a specified goal, where, for example, measurements may be utilized for calibration. The DRILLOPS framework provides flexibility to modify and replan activities dynamically, for example, based on a live appraisal of various factors (e.g., equipment, personnel, and supplies). Well construction activities (e.g., tripping, drilling, cementing, etc.) may be continually monitored and dynamically updated using feedback from operational activities. The DRILLOPS framework may provide for various levels of automation based on planning and/or re-planning (e.g., via the DRILLPLAN framework), feedback, etc.

The PETREL framework may be part of the DELFI environment for utilization in geosciences and geoengineering, for example, to analyze subsurface data from exploration to production of fluid from a reservoir. The DELFI cognitive exploration and production (E&P) environment (SLB, Houston, Texas), referred to herein as the DELFI environment or DELFI framework, is a secure, cognitive, cloud-based collaborative environment that integrates data and workflows with digital technologies, such as artificial intelligence and machine learning.

The PETREL framework provides components that allow for optimization of various exploration, development and production operations. The PETREL framework includes seismic to simulation software components that may output information for use in increasing reservoir performance, for example, by improving asset team productivity. Through use of such a framework, various professionals (e.g., geophysicists, geologists, and reservoir engineers) may develop collaborative workflows and integrate operations to streamline processes (e.g., with respect to one or more geologic environments, etc.). Such a framework may be considered an application (e.g., executable using one or more devices) and may be considered a data-driven application (e.g., where data is input for purposes of modeling, simulating, etc.).

The TECHLOG framework may handle and process field and laboratory data for a variety of geologic environments (e.g., deepwater exploration, shale, etc.). The TECHLOG framework may structure wellbore data for analyses, planning, etc.

The PETROMOD framework provides petroleum systems modeling capabilities that may combine one or more of seismic, well, and geological information to model the evolution of a sedimentary basin. The PETROMOD framework may predict if, and how, a reservoir has been charged with hydrocarbons, including the source and timing of hydrocarbon generation, migration routes, quantities, and hydrocarbon type in the subsurface or at surface conditions.

The ECLIPSE framework provides a reservoir simulator (e.g., as a computational framework) with numerical solutions for fast and accurate prediction of dynamic behavior for various types of reservoirs and development schemes.

The INTERSECT framework provides a high-resolution reservoir simulator for simulation of detailed geological features and quantification of uncertainties, for example, by creating accurate production scenarios and, with the integration of precise models of the surface facilities and field operations, the INTERSECT framework may produce reliable results, which may be continuously updated by real-time data exchanges (e.g., from one or more types of data acquisition equipment in the field that may acquire data during one or more types of field operations, etc.). The INTERSECT framework may provide completion configurations for complex wells where such configurations may be built in the field, may provide detailed enhanced-oil-recovery (EOR) formulations where such formulations may be implemented in the field, may analyze application of steam injection and other thermal EOR techniques for implementation in the field, advanced production controls in terms of reservoir coupling and flexible field management, and flexibility to script customized solutions for improved modeling and field management control. The INTERSECT framework, as with the other example frameworks, may be utilized as part of the DELFI environment, for example, for rapid simulation of multiple concurrent cases. For example, a workflow may utilize one or more of the DELFI environment on demand reservoir simulation features.

The aforementioned DELFI environment provides various features for workflows as to subsurface analysis, planning, construction and production, for example, as illustrated in the workspace framework 110. As shown in FIG. 1, outputs from the workspace framework 110 may be utilized for directing, controlling, etc., one or more processes in the geologic environment 150 and, feedback 160, may be received via one or more interfaces in one or more forms (e.g., acquired data as to operational conditions, equipment conditions, environment conditions, etc.).

As an example, a workflow may progress to a geology and geophysics (“G&G”) service provider, which may generate a well trajectory, which may involve execution of one or more G&G frameworks (e.g., consider the PETREL framework, etc.).

As an example, a platform, such as, for example, the LUMI platform (SLB, Houston, Texas) may be utilized. The LUMI platform includes features that provide for artificial intelligence solutions as may be integrated with data management capabilities. The LUMI platform provides for flexible deployment options and an open, secure, and modular architecture, for example, to empower data-driven decision-making. The LUMI platform is operable with the DELFI environment and, hence, one or more of various frameworks. While various platforms, environments, frameworks, libraries, etc., are mentioned, a framework may be operable in an agnostic manner, for example, to be compatible with one or more other platforms, environments, frameworks, libraries, technologies, etc.

In the example of FIG. 1, the visualization features 123 may be implemented via the workspace framework 110, for example, to perform tasks as associated with one or more of subsurface regions, planning operations, constructing wells and/or surface fluid networks, and producing from a reservoir.

As an example, a visualization process may implement one or more of various features that may be suitable for one or more web applications. For example, a template may involve use of the JAVASCRIPT object notation format (JSON) and/or one or more other languages/formats. As an example, a framework may include one or more converters. For example, consider a JSON to PYTHON converter and/or a PYTHON to JSON converter. Such an approach may provide for compatibility of devices, frameworks, etc., with respect to one or more sets of instructions.

As an example, visualization features may provide for visualization of various earth models, properties, etc., in one or more dimensions. As an example, visualization features may provide for rendering of information in multiple dimensions, which may optionally include multiple resolution rendering. In such an example, information being rendered may be associated with one or more frameworks and/or one or more data stores. As an example, visualization features may include one or more control features for control of equipment, which may include, for example, field equipment that may perform one or more field operations. As an example, a workflow may utilize one or more frameworks to generate information that may be utilized to control one or more types of field equipment (e.g., drilling equipment, wireline equipment, fracturing equipment, etc.).

As to a reservoir model that may be suitable for utilization by a simulator, consider acquisition of seismic data as acquired via reflection seismology, which finds use in geophysics, for example, to estimate properties of subsurface formations. As an example, reflection seismology may provide seismic data representing waves of elastic energy (e.g., as transmitted by P-waves and S-waves, in a frequency range of approximately 1 Hz to approximately 100 Hz). Seismic data may be processed and interpreted, for example, to understand better composition, fluid content, extent and geometry of subsurface rocks. Such interpretation results may be utilized to plan, simulate, perform, etc., one or more operations for production of fluid from a reservoir (e.g., reservoir rock, etc.).

As an example, a model may be a simulated version of a geologic environment. As an example, a simulator may include features for simulating physical phenomena in a geologic environment based at least in part on a model or models. A simulator, such as a reservoir simulator, may simulate fluid flow in a geologic environment based at least in part on a model that may be generated via a framework that receives seismic data. A simulator may be a computerized system (e.g., a computing system) that may execute instructions using one or more processors to solve a system of equations that describe physical phenomena subject to various constraints. In such an example, the system of equations may be spatially defined (e.g., numerically discretized) according to a spatial model that that includes layers of rock, geobodies, etc., that have corresponding positions that may be based on interpretation of seismic and/or other data. A spatial model may be a cell-based model where cells are defined by a grid (e.g., a mesh). A cell in a cell-based model may represent a physical area or volume in a geologic environment where the cell may be assigned physical properties (e.g., permeability, fluid properties, etc.) that may be germane to one or more physical phenomena (e.g., fluid volume, fluid flow, pressure, etc.). A reservoir simulation model may be a spatial model that may be cell-based.

While several simulators are illustrated in the example of FIG. 1, one or more other simulators may be utilized, additionally or alternatively. For example, consider the VISAGE geomechanics simulator (SLB, Houston Texas) or the PIPESIM network simulator (SLB, Houston Texas), etc.

As an example, a workflow may utilize one or more types of data for one or more processes (e.g., stratigraphic modeling, basin modeling, completion designs, drilling, production, injection, etc.). As an example, one or more tools may provide data that may be used in a workflow or workflows that may implement one or more frameworks (e.g., PETREL, TECHLOG, PETROMOD, ECLIPSE, etc.).

In the example of FIG. 1, drilling may be performed in the geologic environment 150, for example, to access the reservoir 151, which may be accessed from land or offshore. In FIG. 1, the downhole equipment 154 may be, for example, part of a bottom hole assembly (BHA). The BHA may be used to drill a well. The downhole equipment 154 may communicate information to equipment at the surface, and may receive instructions and information from the equipment at the surface. During a well construction process, a variety of operations (such as cementing, wireline evaluation, testing, etc.) may be conducted. In such embodiments, data collected by tools and sensors and used for reasons such as reservoir characterization may be collected and transmitted.

A well may include a substantially horizontal portion (e.g., lateral portion) that may intersect with one or more fractures. For example, a well in a shale formation may pass through natural fractures, artificial fractures (e.g., hydraulic fractures), or a combination thereof. Such a well may be constructed using directional drilling techniques as described herein. However, these same techniques may be used in connection with other types of directional wells (such as slant wells, S-shaped wells, deep inclined wells, and others) and are not limited to horizontal wells.

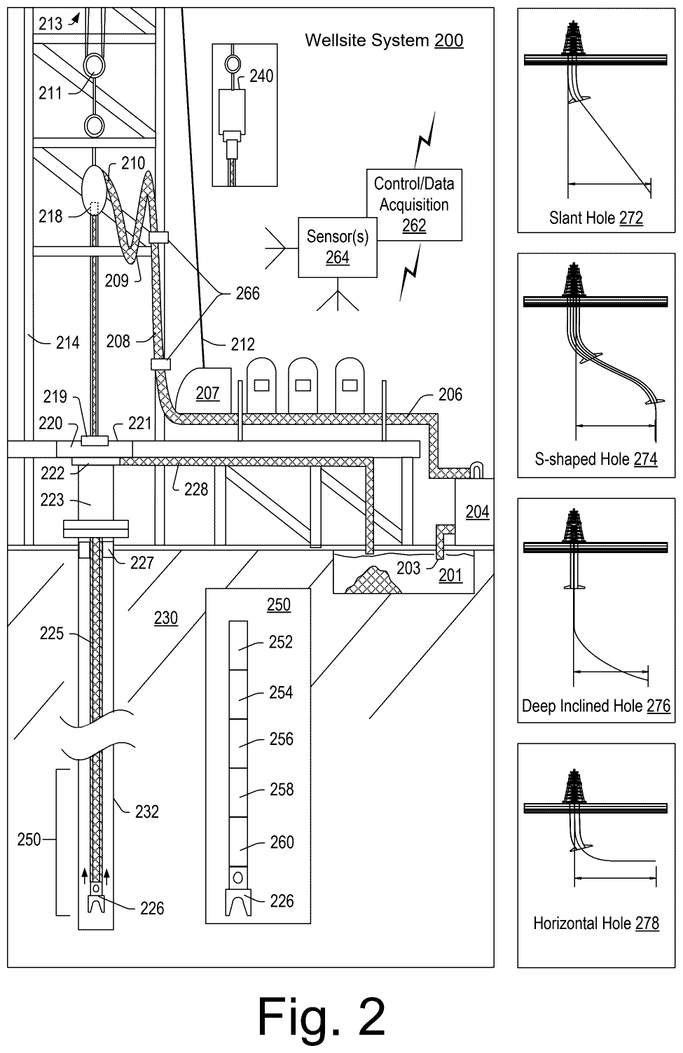

FIG. 2 shows an example of a wellsite system 200 (e.g., at a wellsite that may be onshore or offshore). As shown, the wellsite system 200 may include a mud tank 201 for holding mud and other material (e.g., where mud may be a drilling fluid), a suction line 203 that serves as an inlet to a mud pump 204 for pumping mud from the mud tank 201 such that mud flows to a vibrating hose 206, a drawworks 207 for winching drill line or drill lines 212, a standpipe 208 that receives mud from the vibrating hose 206, a kelly hose 209 that receives mud from the standpipe 208, a gooseneck or goosenecks 210, a traveling block 211, a crown block 213 for carrying the traveling block 211 via the drill line or drill lines 212, a derrick 214, a kelly 218 or a top drive 240, a kelly drive bushing 219, a rotary table 220, a drill floor 221, a bell nipple 222, one or more blowout preventors (BOPs) 223, a drillstring 225, a drill bit 226, a casing head 227 and a flow pipe 228 that carries mud and other material to, for example, the mud tank 201.

In the example system of FIG. 2, a borehole 232 is formed in subsurface formations 230 by rotary drilling; noting that various example embodiments may also use one or more directional drilling techniques, equipment, etc.

As shown in the example of FIG. 2, the drillstring 225 is suspended within the borehole 232 and has a drillstring assembly 250 that includes the drill bit 226 at its lower end. As an example, the drillstring assembly 250 may be a bottom hole assembly (BHA).

The wellsite system 200 may provide for operation of the drillstring 225 and other operations. As shown, the wellsite system 200 includes the traveling block 211 and the derrick 214 positioned over the borehole 232. As mentioned, the wellsite system 200 may include the rotary table 220 where the drillstring 225 pass through an opening in the rotary table 220.

As shown in the example of FIG. 2, the wellsite system 200 may include the kelly 218 and associated components, etc., or a top drive 240 and associated components. As to a kelly example, the kelly 218 may be a square or hexagonal metal/alloy bar with a hole drilled therein that serves as a mud flow path. The kelly 218 may be used to transmit rotary motion from the rotary table 220 via the kelly drive bushing 219 to the drillstring 225, while allowing the drillstring 225 to be lowered or raised during rotation. The kelly 218 may pass through the kelly drive bushing 219, which may be driven by the rotary table 220. As an example, the rotary table 220 may include a master bushing that operatively couples to the kelly drive bushing 219 such that rotation of the rotary table 220 may turn the kelly drive bushing 219 and hence the kelly 218. The kelly drive bushing 219 may include an inside profile matching an outside profile (e.g., square, hexagonal, etc.) of the kelly 218; however, with slightly larger dimensions so that the kelly 218 may freely move up and down inside the kelly drive bushing 219.

As to a top drive example, the top drive 240 may provide functions performed by a kelly and a rotary table. The top drive 240 may turn the drillstring 225. As an example, the top drive 240 may include one or more motors (e.g., electric and/or hydraulic) connected with appropriate gearing to a short section of pipe called a quill, that in turn may be screwed into a saver sub or the drillstring 225 itself. The top drive 240 may be suspended from the traveling block 211, so the rotary mechanism is free to travel up and down the derrick 214. As an example, a top drive 240 may allow for drilling to be performed with more joint stands than a kelly/rotary table approach.

In the example of FIG. 2, the mud tank 201 may hold mud, which may be one or more types of drilling fluids. As an example, a wellbore may be drilled to produce fluid, inject fluid or both (e.g., hydrocarbons, minerals, water, etc.).

In the example of FIG. 2, the drillstring 225 (e.g., including one or more downhole tools) may be composed of a series of pipes threadably connected together to form a long tube with the drill bit 226 at the lower end thereof. As the drillstring 225 is advanced into a wellbore for drilling, at some point in time prior to or coincident with drilling, the mud may be pumped by the pump 204 from the mud tank 201 (e.g., or other source) via the lines 206, 208 and 209 to a port of the kelly 218 or, for example, to a port of the top drive 240. The mud may then flow via a passage (e.g., or passages) in the drillstring 225 and out of ports located on the drill bit 226 (see, e.g., a directional arrow). As the mud exits the drillstring 225 via ports in the drill bit 226, it may then circulate upwardly through an annular region between an outer surface(s) of the drillstring 225 and surrounding wall(s) (e.g., open borehole, casing, etc.), as indicated by directional arrows. In such a manner, the mud lubricates the drill bit 226 and carries heat energy (e.g., frictional or other energy) and formation cuttings to the surface where the mud (e.g., and cuttings) may be returned to the mud tank 201, for example, for recirculation (e.g., with processing to remove cuttings, etc.).

The mud pumped by the pump 204 into the drillstring 225 may, after exiting the drillstring 225, form a mudcake that lines the wellbore which, among other functions, may reduce friction between the drillstring 225 and surrounding wall(s) (e.g., borehole, casing, etc.). A reduction in friction may facilitate advancing or retracting the drillstring 225. During a drilling operation, the entire drillstring 225 may be pulled from a wellbore and optionally replaced, for example, with a new or sharpened drill bit, a smaller diameter drillstring, etc. As mentioned, the act of pulling a drillstring out of a hole or replacing it in a hole is referred to as tripping. A trip may be referred to as an upward trip or an outward trip or as a downward trip or an inward trip depending on trip direction.

As an example, consider a downward trip where upon arrival of the drill bit 226 of the drillstring 225 at a bottom of a wellbore, pumping of the mud commences to lubricate the drill bit 226 for purposes of drilling to enlarge the wellbore. As mentioned, the mud may be pumped by the pump 204 into a passage of the drillstring 225 and, upon filling of the passage, the mud may be used as a transmission medium to transmit energy, for example, energy that may encode information as in mud-pulse telemetry.

As an example, mud-pulse telemetry equipment may include a downhole device configured to effect changes in pressure in the mud to create an acoustic wave or waves upon which information may modulated. In such an example, information from downhole equipment (e.g., one or more modules of the drillstring 225) may be transmitted uphole to an uphole device, which may relay such information to other equipment for processing, control, etc.

As an example, telemetry equipment may operate via transmission of energy via the drillstring 225 itself. For example, consider a signal generator that imparts coded energy signals to the drillstring 225 and repeaters that may receive such energy and repeat it to further transmit the coded energy signals (e.g., information, etc.).

As an example, the drillstring 225 may be fitted with telemetry equipment 252 that includes a rotatable drive shaft, a turbine impeller mechanically coupled to the drive shaft such that the mud may cause the turbine impeller to rotate, a modulator rotor mechanically coupled to the drive shaft such that rotation of the turbine impeller causes said modulator rotor to rotate, a modulator stator mounted adjacent to or proximate to the modulator rotor such that rotation of the modulator rotor relative to the modulator stator creates pressure pulses in the mud, and a controllable brake for selectively braking rotation of the modulator rotor to modulate pressure pulses. In such an example, an alternator may be coupled to the aforementioned drive shaft where the alternator includes at least one stator winding electrically coupled to a control circuit to selectively short the at least one stator winding to electromagnetically brake the alternator and thereby selectively brake rotation of the modulator rotor to modulate the pressure pulses in the mud.

In the example of FIG. 2, an uphole control and/or data acquisition system 262 may include circuitry to sense pressure pulses generated by telemetry equipment 252 and, for example, communicate sensed pressure pulses or information derived therefrom for process, control, etc.

The assembly 250 of the illustrated example includes a logging-while-drilling (LWD) module 254, a measurement-while-drilling (MWD) module 256, an optional module 258, a rotary-steerable system (RSS) and/or motor 260, and the drill bit 226. Such components or modules may be referred to as tools where a drillstring may include a plurality of tools.

As to an RSS, it involves technology utilized for directional drilling. Directional drilling involves drilling into the Earth to form a deviated bore such that the trajectory of the bore is not vertical; rather, the trajectory deviates from vertical along one or more portions of the bore. As an example, consider a target that is located at a lateral distance from a surface location where a rig may be stationed. In such an example, drilling may commence with a vertical portion and then deviate from vertical such that the bore is aimed at the target and, eventually, reaches the target. Directional drilling may be implemented where a target may be inaccessible from a vertical location at the surface of the Earth, where material exists in the Earth that may impede drilling or otherwise be detrimental (e.g., consider a salt dome, etc.), where a formation is laterally extensive (e.g., consider a relatively thin yet laterally extensive reservoir), where multiple bores are to be drilled from a single surface bore, where a relief well is desired, etc.

One approach to directional drilling involves a mud motor; however, a mud motor may present some challenges depending on factors such as rate of penetration (ROP), transferring weight to a bit (e.g., weight on bit, WOB) due to friction, etc. A mud motor may be a positive displacement motor (PDM) that operates to drive a bit (e.g., during directional drilling, etc.). A PDM operates as drilling fluid is pumped through it where the PDM converts hydraulic power of the drilling fluid into mechanical power to cause the bit to rotate.

As an example, a mud motor (e.g., PDM) may be operated in different modes, which may include a rotating mode and a sliding mode. A sliding mode involves drilling with a mud motor rotating the bit downhole without rotating the drillstring from the surface. Such an operation may be conducted when a BHA has been fitted with a bent sub or a bent housing mud motor, or both, for directional drilling. Sliding may be used in building and controlling or adjusting hole angle. In directional drilling, pointing of a bit may be accomplished through a bent sub, which may have a relatively small angle offset from the axis of a drillstring, and a measurement device to determine the direction of offset. Without turning the drillstring, the bit may be rotated with mud flow through the mud motor to drill in the direction it is pointed. With steerable motors, when a desired wellbore direction is attained, the entire drillstring may be rotated to drill straight rather than at an angle. By controlling the amount of hole drilled in the sliding mode versus the rotating mode, a wellbore trajectory may be controlled rather precisely.

As an example, a PDM may operate in a combined rotating mode where surface equipment is utilized to rotate a bit of a drillstring (e.g., a rotary table, a top drive, etc.) by rotating the entire drillstring and where drilling fluid is utilized to rotate the bit of the drillstring. In such an example, a surface RPM (SRPM) may be determined by use of the surface equipment and a downhole RPM of the mud motor may be determined using various factors related to flow of drilling fluid, mud motor type, etc. As an example, in the combined rotating mode, bit RPM may be determined or estimated as a sum of the SRPM and the mud motor RPM, assuming the SRPM and the mud motor RPM are in the same direction.

As an example, a PDM mud motor may operate in a so-called sliding mode, when the drillstring is not rotated from the surface. In such an example, a bit RPM may be determined or estimated based on the RPM of the mud motor.

An RSS may drill directionally where there is continuous rotation from surface equipment, which may alleviate the sliding of a steerable motor (e.g., a PDM). An RSS may be deployed when drilling directionally (e.g., deviated, horizontal, or extended-reach wells). An RSS may aim to minimize interaction with a borehole wall, which may help to preserve borehole quality. An RSS may aim to exert a relatively consistent side force akin to stabilizers that rotate with the drillstring or orient the bit in the desired direction while continuously rotating at the same number of rotations per minute as the drillstring.

The LWD module 254 may be housed in a suitable type of drill collar and may contain one or a plurality of selected types of logging tools. It will also be understood that more than one LWD and/or MWD module may be employed. Where the position of an LWD module is mentioned, as an example, it may refer to a module at the position of the LWD module 254, the MWD module 256, etc. An LWD module may include capabilities for measuring, processing, and storing information, as well as for communicating with the surface equipment. In the illustrated example, the LWD module 254 may include a seismic measuring device.

The MWD module 256 may be housed in a suitable type of drill collar and may contain one or more devices for measuring characteristics of the drillstring 225 and the drill bit 226. As an example, the MWD module 256 may include equipment for generating electrical power, for example, to power various components of the drillstring 225. As an example, the MWD module 256 may include the telemetry equipment 252, for example, where the turbine impeller may generate power by flow of the mud; it being understood that other power and/or battery systems may be employed for purposes of powering various components. As an example, the MWD module 256 may include one or more of the following types of measuring devices: a weight-on-bit measuring device, a torque measuring device, a vibration measuring device, a shock measuring device, a stick slip measuring device, a direction measuring device, and an inclination measuring device.

FIG. 2 also shows some examples of types of holes that may be drilled. For example, consider a slant hole 272, an S-shaped hole 274, a deep inclined hole 276 and a horizontal hole 278.

As an example, a drilling operation may include directional drilling where, for example, at least a portion of a well includes a curved axis. For example, consider a radius that defines curvature where an inclination with regard to the vertical may vary until reaching an angle between about 30 degrees and about 60 degrees or, for example, an angle to about 90 degrees or possibly greater than about 90 degrees.

As an example, a directional well may include several shapes where each of the shapes may aim to meet particular operational demands. As an example, a drilling process may be performed on the basis of information as and when it is relayed to a drilling engineer. As an example, inclination and/or direction may be modified based on information received during a drilling process.

As an example, deviation of a bore may be accomplished in part by use of a downhole motor and/or a turbine. As to a motor, for example, a drillstring may include a positive displacement motor (PDM).

As an example, a system may be a steerable system and include equipment to perform method such as geosteering. As mentioned, a steerable system may be or include an RSS. As an example, a steerable system may include a PDM or of a turbine on a lower part of a drillstring which, just above a drill bit, a bent sub may be mounted. As an example, above a PDM, MWD equipment that provides real time or near real time data of interest (e.g., inclination, direction, pressure, temperature, real weight on the drill bit, torque stress, etc.) and/or LWD equipment may be installed. As to the latter, LWD equipment may make it possible to send to the surface various types of data of interest, including for example, geological data (e.g., gamma ray log, resistivity, density and sonic logs, etc.).

The coupling of sensors providing information on the course of a well trajectory, in real time or near real time, with, for example, one or more logs characterizing the formations from a geological viewpoint, may allow for implementing a geosteering method. Such a method may include navigating a subsurface environment, for example, to follow a desired route to reach a desired target or targets.

As an example, a drillstring may include an azimuthal density neutron (ADN) tool for measuring density and porosity; a MWD tool for measuring inclination, azimuth and shocks; a compensated dual resistivity (CDR) tool for measuring resistivity and gamma ray related phenomena; one or more variable gauge stabilizers; one or more bend joints; and a geosteering tool, which may include a motor and optionally equipment for measuring and/or responding to one or more of inclination, resistivity and gamma ray related phenomena.

As an example, geosteering may include intentional directional control of a wellbore based on results of downhole geological logging measurements in a manner that aims to keep a directional wellbore within a desired region, zone (e.g., a pay zone), etc. As an example, geosteering may include directing a wellbore to keep the wellbore in a particular section of a reservoir, for example, to minimize gas and/or water breakthrough and, for example, to maximize economic production from a well that includes the wellbore.

Referring again to FIG. 2, the wellsite system 200 may include one or more sensors 264 that are operatively coupled to the control and/or data acquisition system 262. As an example, a sensor or sensors may be at surface locations. As an example, a sensor or sensors may be at downhole locations. As an example, a sensor or sensors may be at one or more remote locations that are not within a distance of the order of about one hundred meters from the wellsite system 200. As an example, a sensor or sensor may be at an offset wellsite where the wellsite system 200 and the offset wellsite are in a common field (e.g., oil and/or gas field).

As an example, one or more of the sensors 264 may be provided for tracking pipe, tracking movement of at least a portion of a drillstring, etc.

As an example, the system 200 may include one or more sensors 266 that may sense and/or transmit signals to a fluid conduit such as a drilling fluid conduit (e.g., a drilling mud conduit). For example, in the system 200, the one or more sensors 266 may be operatively coupled to portions of the standpipe 208 through which mud flows. As an example, a downhole tool may generate pulses that may travel through the mud and be sensed by one or more of the one or more sensors 266. In such an example, the downhole tool may include associated circuitry such as, for example, encoding circuitry that may encode signals, for example, to reduce demands as to transmission. As an example, circuitry at the surface may include decoding circuitry to decode encoded information transmitted at least in part via mud-pulse telemetry. As an example, circuitry at the surface may include encoder circuitry and/or decoder circuitry and circuitry downhole may include encoder circuitry and/or decoder circuitry. As an example, the system 200 may include a transmitter that may generate signals that may be transmitted downhole via mud (e.g., drilling fluid) as a transmission medium.

As an example, one or more portions of a drillstring may become stuck. The term stuck may refer to one or more of varying degrees of inability to move or remove a drillstring from a bore. As an example, in a stuck condition, it might be possible to rotate pipe or lower it back into a bore or, for example, in a stuck condition, there may be an inability to move the drillstring axially in the bore, though some amount of rotation may be possible. As an example, in a stuck condition, there may be an inability to move at least a portion of the drillstring axially and rotationally.

As to the term “stuck pipe”, this may refer to a portion of a drillstring that cannot be rotated or moved axially. As an example, a condition referred to as “differential sticking” may be a condition whereby the drillstring cannot be moved (e.g., rotated or reciprocated) along the axis of the bore. Differential sticking may occur when high-contact forces caused by low reservoir pressures, high wellbore pressures, or both, are exerted over a sufficiently large area of the drillstring. Differential sticking may have time and financial cost.

As an example, a sticking force may be a product of the differential pressure between the wellbore and the reservoir and the area that the differential pressure is acting upon. This means that a relatively low differential pressure (delta p) applied over a large working area may be just as effective in sticking pipe as may a high differential pressure applied over a small area.

As an example, a condition referred to as “mechanical sticking” may be a condition where limiting or prevention of motion of the drillstring by a mechanism other than differential pressure sticking occurs. Mechanical sticking may be caused, for example, by one or more of junk in the hole, wellbore geometry anomalies, cement, keyseats or a buildup of cuttings in the annulus.

As explained, a wellsite system may include various types of equipment for handling fluid such as, for example, drilling fluid (e.g., mud). As explained, drilling fluid may provide one or more functions (e.g., lubrication, transport of cutting, etc.).

Drilling fluid may be composed of a number of liquid and/or gaseous fluids and mixtures of fluids and solids (e.g., as solid suspensions, mixtures and emulsions of liquids, gases and solids) as may be used in various operations to drill boreholes into the earth. Classifications of drilling fluids may utilize one or more types of classification schemes. For example, consider water-based mud (WBM), oil-based mud (OBM), nonaqueous-based mud (NQBM), gaseous-based mud (e.g., pneumatic, etc.) (GBM), etc.

As an example, drilling fluid may be lost to a formation and/or reservoir fluid may enter drilling fluid. Hence, one or more functions of drilling fluid may be compromised by changes to drilling fluid. For example, if density of drilling fluid is altered by introduction of reservoir fluid, the drilling fluid may diminish in its ability to transport cuttings to surface. As a consequence, cuttings may build up within an annulus between a drillstring and a borehole wall or cased wellbore, which may increase risk of sticking (e.g., stuck pipe). To address changes to drilling fluid, one or more actions may be taken, for example, consider adding one or more components to the drilling fluid, adding additional drilling fluid, etc.

As to lost circulation or circulation loss, these terms may refer to loss of drilling fluid to a formation, for example, caused when the hydrostatic head pressure of the column of drilling fluid exceeds the formation pressure. This loss of fluid may be loosely classified as seepage losses, partial losses, or catastrophic losses, each of which may be handled differently depending on the risk to equipment, materials, borehole quality, characteristics of drilling fluid, personnel, etc.

As to influx of formation fluid (e.g., reservoir fluid, etc.), it may include an event known as a kick. A kick may be defined as a flow of formation fluid into a bore during drilling operations. A kick may be physically caused by the pressure in the bore being less than that of the formation fluid, thus causing flow. This condition of lower bore pressure than formation pressure may be caused in various ways. For example, if mud weight is too low, then hydrostatic pressure exerted on a formation by the fluid column may be insufficient to hold the formation fluid in the formation. This may happen if the mud density is suddenly lightened or is not to specification to begin with, or if a drilled formation has a higher pressure than expected. This type of kick might be called an underbalanced kick. As another example, consider a kick that may occur if dynamic and transient fluid pressure effects (e.g., due to motion of the drillstring or casing), effectively lower the pressure in a bore below that of the formation. Such a type of kick may be referred to as an induced kick.

Additional phenomena that may occur during drilling operations include swab and surge. As to swab, it may involve a reduction in pressure in a bore by moving pipe, wireline tools or where rubber-cupped seals up the bore. If the pressure is reduced sufficiently, reservoir fluid may flow into the bore and towards surface. Swabbing tends to be detrimental in drilling operations as it may lead to kick and borewall stability problems. As to surge, consider an example where a drillstring is being tripped-out (e.g., pulled out of hole (POOH)) where upward movement of the drillstring causes friction between the drillstring and drilling fluid. In surge, pressure may decrease in a bore due to the surge effect; noting that the opposite effect may happen when a drillstring is tripping-in (e.g., running in hole (RIH)), as downward movement may cause a pressure increase (e.g., a swab effect).

As explained, a drillstring may include a mud motor that is rotationally driven by flow of drilling fluid. In such a mode of drilling, the characteristics of drilling fluid may impact mud motor performance. For example, density (e.g., mud weight) may impact how much energy the mud motor may deliver to a drill bit for a given drilling fluid flow rate.

As to a stuck pipe or risk of sticking event, as explained, one or more actions may be taken. For example, consider addition of acid as a remedial action to address the stuck pipe event or to reduce the risk of a sticking event. In such an example, a number of barrels of acid may be added to drilling fluid that is circulated downhole to an annular region between a drilling string and a bore wall in an effort to “dissolve” material that is causing sticking or a risk of sticking. While addition of acid is mentioned, it may be an action within a tiered series of actions that may be taken, where, for example, each action may have associated benefits and detriments. As to detriments, these may include non-productive time (NPT), cost, further remedial actions (e.g., impact of acid on one or more additives in drilling fluid), etc. Hence, where an event occurs or a risk of an event is heightened, in an effort to maintain adherence to a plan, one or more actions may be implemented in a strategic manner to resolve the event or otherwise reduce the risk.

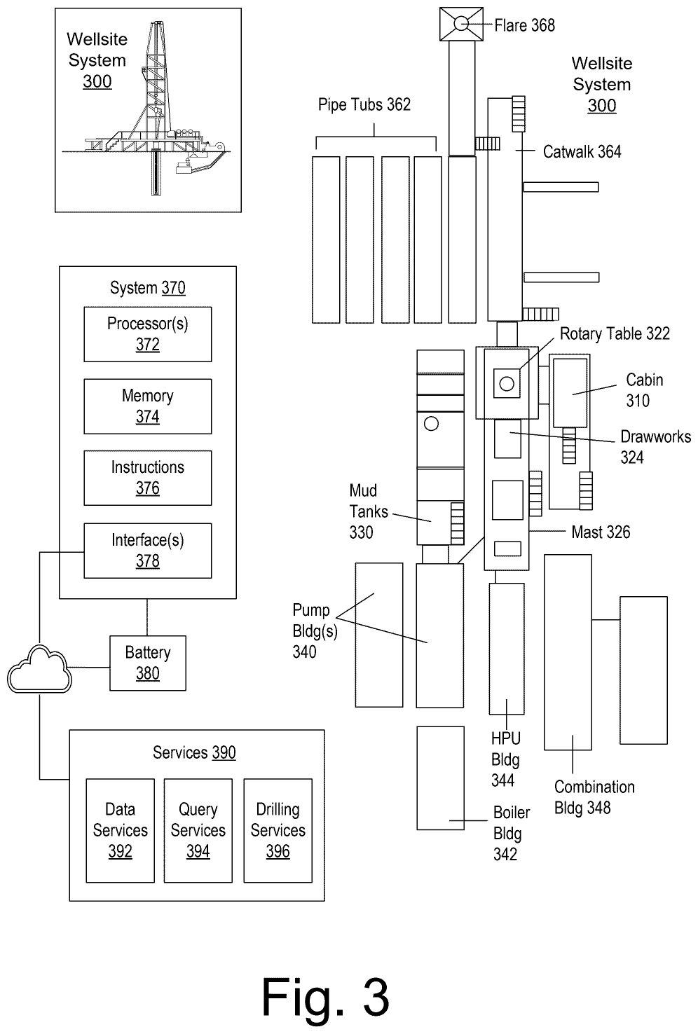

FIG. 3 shows an example of a wellsite system 300, specifically, FIG. 3 shows the wellsite system 300 in an approximate side view and an approximate plan view along with a block diagram of a system 370.

In the example of FIG. 3, the wellsite system 300 may include a cabin 310, a rotary table 322, drawworks 324, a mast 326 (e.g., optionally carrying a top drive, etc.), mud tanks 330 (e.g., with one or more pumps, one or more shakers, etc.), one or more pump buildings 340, a boiler building 342, an HPU building 344 (e.g., with a rig fuel tank, etc.), a combination building 348 (e.g., with one or more generators, etc.), pipe tubs 362, a catwalk 364, a flare 368, etc. Such equipment may include one or more associated functions and/or one or more associated operational risks, which may be risks as to time, resources, and/or humans.

As shown in the example of FIG. 3, the wellsite system 300 may include a system 370 that includes one or more processors 372, memory 374 operatively coupled to at least one of the one or more processors 372, instructions 376 that may be, for example, stored in the memory 374, and one or more interfaces 378. As an example, the system 370 may include one or more processor-readable media that include processor-executable instructions executable by at least one of the one or more processors 372 to cause the system 370 to control one or more aspects of the wellsite system 300. In such an example, the memory 374 may be or include the one or more processor-readable media where the processor-executable instructions may be or include instructions. As an example, a processor-readable medium may be a computer-readable storage medium that is not a signal and that is not a carrier wave.

FIG. 3 also shows a battery 380 that may be operatively coupled to the system 370, for example, to power the system 370. As an example, the battery 380 may be a back-up battery that operates when another power supply is unavailable for powering the system 370. As an example, the battery 380 may be operatively coupled to a network, which may be a cloud network. As an example, the battery 380 may include smart battery circuitry and may be operatively coupled to one or more pieces of equipment via a SMBus or other type of bus.

In the example of FIG. 3, services 390 are shown as being available, for example, via a cloud platform. Such services may include data services 392, query services 394 and drilling services 396. As an example, the services 390 may be part of a system such as the system 100 of FIG. 1 (e.g., consider planning services and/or operational services). As an example, the services 390 may include one or more services for directional drilling (e.g., consider a computational framework that may provide for one or more services that utilize real-time data to estimate one or more parameters, etc.).

As an example, the system 370 may be utilized to generate one or more rate of penetration drilling parameter values, which may, for example, be utilized to control one or more drilling operations.

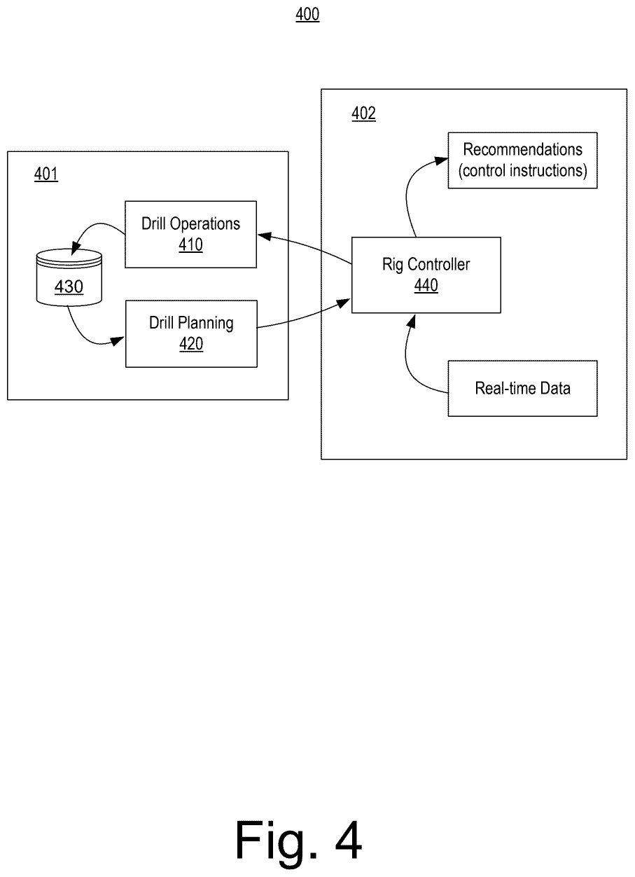

FIG. 4 shows an example of a system 400 that includes offsite equipment 401 (e.g., remote) and onsite equipment 402 (e.g., local). As shown, the offsite equipment 401 may include a drill operations framework 410, a drill planning framework 420 and a database 430 and the onsite equipment 402 may include a controller 440 that may receive real-time data and output recommendations such as control instructions to control onsite equipment. In such an example, the drill operations framework 410 may provide for steering sheets, execution parameters, etc., and the drill planning framework 420 may provide for evaluation of steering responses and statistics. As shown, the controller 440 may output information to the drill operations framework 410 and receive information from the drill planning framework 420. The system 400 may include plan generation features for real-time plan generation during drilling operations execution phase and/or plan generation during a planning phase. The system 400 may be utilized for one or more types of drilling (e.g., rotary, mud motor, RSS, ABSS, etc.). The system 400 may operate loops, which may include at least one real-time loop that provides for control of equipment to perform drilling operations.

A system such as the system 400 may utilize various functions and constraints for generation of plans, which may provide for single or multiple target aiming. As explained, a plan may be generated that aims to provide for drilling operations for a mutliwell structure. As explained, a plan may be a digital plan that may be utilized to instruct one or more controllers such as, for example, an autodriller controller, which may control one or more pieces of equipment (e.g., a drawworks, a top drive, one or more drilling fluid pumps, etc.). As an example, an autodriller may control energy delivered via one or more pieces of equipment to a drill bit where the drill bit crushes and/or cuts rock to extend a borehole. As an example, an autodriller may be controlled in an effort that aims to minimize or otherwise reduce mechanical specific energy (MSE) and to maximize or otherwise increase rate of penetration (ROP).

As explained with respect to the system 100 of FIG. 1, various computational frameworks may be utilized to perform one or more workflows, which may include planning workflows, workflows involving control of field operations, workflows in real-time or near real-time, assessment workflows (e.g., for issues, successes, etc.), etc. As explained, one or more visualization features may be provided and utilized, for example, to implement visualization processes that may be suitable for one or more web applications. As mentioned, JSON and/or one or more other languages and/or formats may be utilized.

As an example, one or more graphical user interface (GUI) toolkits may be utilized for generation of one or more GUIs. As an example, a GUI may be a widget or may include widgets. A widget may be utilized as a generic term to describe elements that make up a GUI (e.g., buttons, labels, windows, etc.). In the PySimpleGUI toolkit, widgets may be referred to as elements. For example, consider the Window () building block in the PySimpleGUI toolkit. In such an example, to create a Window () consider the following PYTHON language code (e.g., Py code):
#hello_world.py
import PySimpleGUI as sg
sg.Window(title=“Hello World”, layout=[[]], margins=(100, 50)).read ()

As an example, the Window () building block may take various different arguments, for example, in the foregoing example the Window () building block includes a title, a layout, and set the margins, which defines the size of the GUI window in pixels. As to the building block read () it returns one or more events that may be triggered in the Window () as a string as well as a values dictionary.

In various instances, a GUI may include graphics that may be rendered, for example, using vector graphics instructions. As to the aforementioned PySimpleGUI toolkit, it may be integrated with other features such as, for example, numpy and matplotlib. Below, an example of PYTHON language code includes import commands to import various features such that a plot may be rendered in a GUI:
import numpy as np
from matplotlib.backends.backend_tkagg import FigureCanvasTkAgg
import PySimpleGUI as sg
import matplotlib
fig=matplotlib.figure.Figure(figsize=(5, 4), dpi=100)
t=np.arange(0, 3, 0.1)
fig.add_subplot(111).plot(t, 2*np.sin(2*np.pi*t))

In the foregoing example, which tends to be relatively simply (e.g., a single plot in a GUI), various arguments (e.g., parameters) are specified. As to the example computational frameworks 121 of FIG. 1, GUIs may be more complex and include various parameters, some of which may be user configurable. For example, a GUI may include sub-GUIs that may be rendered from a menu, etc., to allow a user to configure colors, types of plots, units, layouts of elements, etc. As an example, a workflow may involve navigating through multiple GUIs where one or more of the multiple GUIs may be at least in part configurable by a user. In various instances, a user may customize (e.g., personalize) a GUI, for herself, for a team, for a company, etc. Customization may facilitate collaboration and/or otherwise sharing of information, results, actions, etc. The task of GUI customization may be tedious and time consuming, which may result in non-productive time (NPT). Further, a user may not remember all of the customizable options provided by a GUI or GUIs. Hence, a user may have to resort to asking others, looking for information in a manual, trial and error, doing tasks with what is easiest or known, etc. Such an approach to workflows may be inefficient and may pose risks of losing information for purposes of communication, archiving, compliance, etc.

While matplotlib is mentioned in the foregoing example code, one or more other types of libraries may be utilized, additionally or alternatively. For example, consider the plotly library (Plotly, Montreal, Canada), which provides tools for online graphing, analytics, statistics, etc., as well as access to various scientific graphing libraries with respect to one or more platforms (e.g., PYTHON, R, MATLAB, PERL, JULIA, ARDUINO, JAVASCRIPT, REST, etc.).

As an example, a framework may utilize one or more platforms, libraries, etc., for rendering GUIs. For example, consider using matplotlib to create static plots and charts in data visualization and DASH (Plotly, Montreal, Canada) for interactive web applications. As an example, a GUI may incorporation various interactive components such as, for example, one or more of dropdown menus, sliders, and buttons, which may allow for dynamic modification of data and observation of real-time updates in matplotlib. As an example, a framework may provide for combining features of matplotlib, PYTHON, and DASH to generate engaging web apps, such as, for example, GUIs for dashboards, scientific visualizations, business intelligence tools, etc.

As an example, a drilling operations framework may provide for learning parameters and their values (e.g., settings, etc.) and expediting workflows by generating one or more GUIs with appropriate parameters and values. Such an approach may enhance communication, archiving, compliance, etc. As an example, a GUI may be a dashboard and/or a dashboard may include one or more GUIs (e.g., sub-GUIs).

As explained, time and skills may be required to create specific dashboards to visualize drilling operations (e.g., conditions, plans, actions, events, etc.). As mentioned, a drilling operations framework may reduce demands on an individual (e.g., a drilling engineer, etc.), which may expedite and/or otherwise improve field operations, decision-making, etc. As an example, a drilling operations framework may provide for use of generative artificial intelligence (GenAI). For example, consider a GUI, as an introductory GUI or otherwise instantiated (e.g., called responsive to an event, a workflow task, etc.), that may be utilized by an individual to enter (e.g., via text, selections, etc.) information as to a task, a workflow, a project, a team, a company, etc., where, in response, a drilling operations framework may configure one or more GUIs. For example, consider a drilling engineer that interacts with a GenAI GUI to prompt a GenAI engine as to a type of event or operation the drilling engineer wants to analyze, for example, along with one or more other aspects (e.g., a time interval, depth, a depth interval, etc.).

As an example, a GenAI engine may be trained on existing dashboards that include individual visualizations (e.g., elements or widgets, etc.). In such an example, the GenAI engine may respond to a prompt from a user by determining what type of event and/or operation is to be visualized such that the GenAI engine may propose a combination of widgets and a layout. In such an example, the widgets and/or the layout may be appropriately configured, for example, according to various parameters and parameter settings. As explained, such an approach may help to reduce an individual's reliance on demands of expertise to compose an analysis and skills to build a visualization. As an example, a GenAI engine may provide for adaption as to changes due to upgrades, etc., of a framework. For example, a GenAI engine may provide information as to timings such as when one or more visualization features of a framework may have been upgraded (e.g., updated, etc.). In such an example, a GenAI engine may provide for rendering of a notification as to such a change and, for example, documentation and/or other information as to the change (e.g., additional features, etc.).

As an example, a drilling operations framework may operate as an intelligent system to visualize relevant data, which may do so with reduced user demand, for example, in a manner that demands little to no expertise or skill beyond requesting what a user wants to visualize. Such a framework may enhance event and operational analyses in the well construction drilling environment as drilling engineers may operate by prompting the framework as to analyses they want to visualize whereby, in response, the framework (e.g., in a matter of seconds or less) generates specific domain visualization configurations (e.g., with multiple graphs to facilitate understanding of relevant information, etc.).

As explained, a framework may leverage GenAI technologies in an upstream drilling domain to provide users (e.g., drilling engineers, etc.) with an ability to build visualizations of domain specific events and operations by prompting a framework with the type of analysis that they wish to conduct. In such an approach, substantial time demands may be placed on a user (e.g., a drilling engineer) such that use of a framework may conserve time and allow for expediting understanding and responses to one or more events, potential events, etc. As an example, a framework may provide for improved drilling operations, for example, by reducing event risks, mitigating events, reducing non-productive time, etc.

As explained, a drilling visualization or dashboard may be composed of one or multiple widgets, which may display specific data that may be in a specific manner of presentation. As an example, a dashboard may be constructed with a specific purpose, such as, for example, to visualize daily operations, visualize drilling performance, visualize drilling parameters, etc. As an example, components or widgets of a dashboard may provide for display of relevant pieces of information, which, when combined, may provide a user with data and/or tools to extract a conclusion (e.g., an actionable field operation, etc.).

As an example, a method may include training a GenAI engine with existing dashboards, descriptions, components, etc., to generate a trained GenAI engine. In such an example, a trained GenAI engine may allow for prompting and, in response, proposing a composition to analyze a specific event a user is concerned with (e.g., consider a drilling engineer concerned with a risk of stuck pipe, lost circulation, bit wear, shock and vibration, etc.). As explained, a trained model may provide for dashboard generation, for example, consider a dashboard with a set of widgets, configured to specifically address a requested domain analysis.

As an example, control of one or more field operations at a wellsite may be facilitated through use of a framework that may provide one or more actions for addressing an event, a risk of an event, etc. For example, consider a framework that may allow an engineer to interact with the framework via one or more graphical user interfaces (GUIs) and/or one or more other types of user interfaces (UIs) (e.g., microphone, QR code, etc.). In such an example, the engineer may enter information regarding an event such as a stuck pipe event, a lost circulation event, etc. In response, the framework may transform input received to a prompt or query that is submitted to one or more large language models (LLMs) that may be enriched with embeddings from historical drilling events and various GUI configurations for handling such events (e.g., addressing risks, tailoring of field operations, etc.). As an example, a framework may utilize one or more LLMs in one or more manners, which may be for training (e.g., generation of training data), implementation (e.g., generation of output responsive to a prompt), etc.

A large language model (LLM) may be a type of language model notable for its ability to achieve general-purpose language understanding and generation. An LLM may acquire abilities by using relatively massive amounts of data to learn parameters (e.g., determine parameter values, etc.) during training. An LLM may be an artificial neural network or networks (e.g., consider a transformer, etc.) and may be trained and/or pre-trained using one or more types of learning (e.g., self-supervised learning, semi-supervised learning, unsupervised learning, etc.).

As an example, an autoregressive language model (e.g., AR LLM) may operate by taking input text and repeatedly predicting a next token or word. As an example, an LLM may be tuned, for example, for a particular domain. As an example, an LLM such as the Generative Pretrained Transformer (GPT) 3 (GPT-3) may be prompt-engineered. As an example, an LLM may acquire embodied knowledge about syntax, semantics and ontology inherent in human language corpora; noting that an LLM may also acquire inaccuracies and biases present in a corpus.

As an example, a machine learning model (ML model), whether an LLM and/or one or more other types of models, may be trained using configuration information (e.g., parameters, parameter settings, etc.) as to one or more types of GUIs for one or more types of workflows. In such an example, an ML model may provide for analysis of images (e.g., screen captures, recreated images, etc.), metadata, etc. As an example, an ML model may provide for learning of sequences performed dependent on time, independent of time (e.g., consider state-based, etc.), etc. As an example, training data may provide for learning configurations of a series of one or more GUIs to perform various workflows.

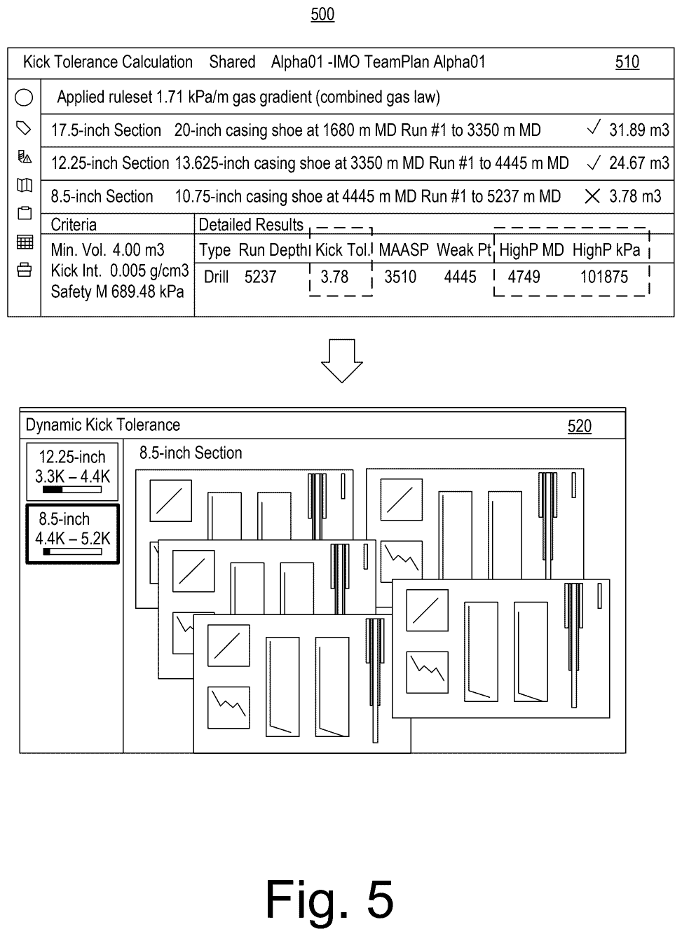

FIG. 5 shows an example of a workflow 500 along with two GUIs 510 and 520 associated with the workflow 500. As shown, the workflow 500 pertains to kick tolerance during drilling. The GUI 510 may be an earlier GUI while the GUI 520 may be a later GUI. As shown, data for various sections of a well are shown in the GUI 510 where the 8.5-inch section is expanded. As an example, a user may enter information into a field of a GenAI engine interface that may include section information such that the GUI 510 is automatically rendered with the 8.5-inch section expanded. As to the GUI 520, it includes a number of plots that may be generated and arranged for the 8.5-inch section of the well of interest. As an example, such plots and an arrangement thereof may be automatically configured responsive to entering a prompt into the GenAI engine interface. In such an approach, a user may expeditiously proceed to analyze one or more types of actual and/or potential kick issues during drilling. In turn, the user may control one or more pieces of field equipment to address a kick or a risk of a kick. As an example, the GUI 510 and/or the GUI 520 may include one or more graphical controls that may be actuated to issue a control instruction. As an example, a GenAI engine interface may be aware of equipment and/or one or more controllers that may be controllable where, for example, a GenAI engine may provide for generating and rendering and appropriately interfacing one or more graphical controls for purposes of equipment control. For example, consider a GenAI engine that may provide for configuring one or more interfaces for making one or more API calls to one or more controllers for controlling field equipment (e.g., for drilling, for kick control, etc.).

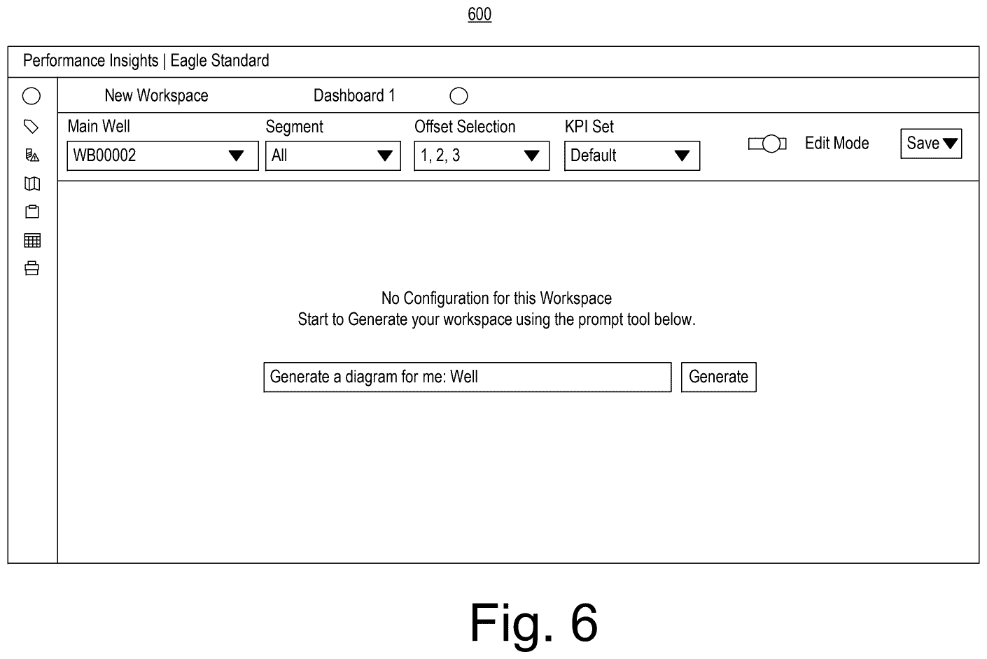

FIG. 6 shows an example GUI 600 that may be an initial GUI for operation of a GenAI engine. As shown, the GUI 600 may include a dashboard panel for a workspace where a message may be rendered as to configuration of the workspace. For example, a field may be rendered where a user may enter a prompt using a prompt tool followed by actuation of a generation button such that the workspace becomes configured, which, as explained, may be an overview dashboard for a workflow, a particular dashboard for the workflow, etc., noting that where a sequence of dashboards (e.g., GUIs) may be utilized for performing a workflow, a number of dashboards may be appropriately configured. As explained, such an approach may provide for control configurations, for example, via one or more interfaces (e.g., APIs, etc.).

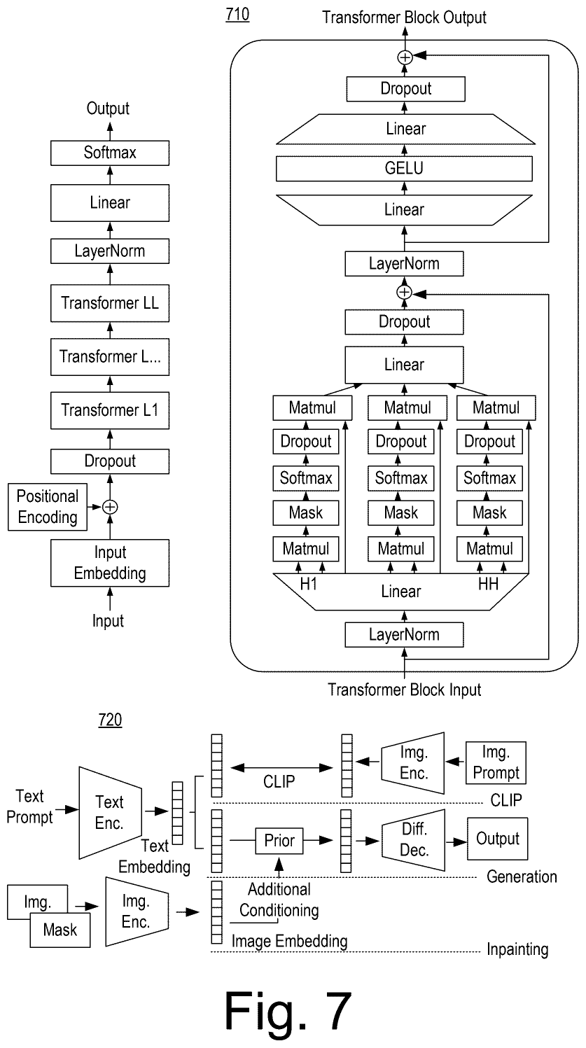

FIG. 7 shows an example architecture 710 of a GPT and an example of an architecture 720 for handling text and images; noting that one or more features of the architectures 710 and 720 may be utilized in a drilling operations framework. As shown, an architecture may include multiple transformer layers where a transformer layer may include a transformer block input and a transformer block output. A transformer layer may include components such as matrix multiplication (matmul), mask, softmax, dropout, Gaussian error linear unit (GELU), etc. As an example, an architecture may include one or more encoders and one or more decoders. For example, consider an architecture with a text encoder that can receive a text prompt and an image encoder that can receive an image and a mask. In such an example, another image encoder may receive an image prompt and a diffusion decoder may generate output.

In the example architecture 720, a Contrastive Language-Image Pre-training (CLIP) approach is indicated where one or more types of graphics may be utilized (e.g., GUIs, GUI elements, plots, diagrams, etc.). As shown in FIG. 7, the architecture 720 may provide for pretraining (see CLIP), text to image training and interference (see Generation), and inpainting training and interference (see Inpainting). Such an approach can generate an image based on a text prompt among other image manipulations and, in addition to the CLIP embeddings generated from the text-to-image actions, in a completion task, four channels of input (RGB channels of an image and a mask channel) may be received. During inference, encodings of the masked input image may then be concatenated to the CLIP embeddings and fed to the prior. In such an approach, a model can learn to fill in masked parts of an image (e.g., inpainting). For example, for inpainting, a ranked number of filtered images may be selected and evaluated by comparing to an original image used for generation and the text prompt used in the inpainting process. As an example, inpainting may lead to modification of an original image.

As an example, a foundational GPT model may be further adapted to produce more targeted systems directed to specific tasks and/or subject-matter domains. Techniques for such adaptation may include additional fine-tuning (e.g., beyond tuning of a foundation model, etc.), certain forms of prompt engineering, etc. As an example, an LLM may be a chatbot type of LLM. For example, consider the OpenAl ChatGPT LLM, which is an online chat interface powered by an instruction-tuned language model trained in a similar fashion to InstructGPT. Other chatbots may include features of GPT-4 (OpenAI), Bard (e.g., LaMDA family of conversation-trained language models, PaLM, etc.) (Google, Mountain View, California), etc.

As an example, a LLM Meta AI (LLAMA) LLM may be utilized, which includes a transformer architecture; noting some architectural differences compared to GPT-3. For example, LLAMA utilizes the SwiGLU activation function rather than ReLU, uses rotary positional embeddings rather than absolute positional embedding, and uses root-mean-squared layer-normalization rather than standard layer-normalization. Further, there may be an increase in context length from 2K (Llama 1) tokens to 4K (Llama 2) tokens between.

As an example, a GenAI engine may utilize one or more features of the DALL⋅E family of text-to-image models (OpenAI, San Francisco, California), which may utilize one or more deep learning techniques to generate digital images from natural language descriptions (e.g., prompts, etc.).

A DALL⋅E model may be provided as a multimodal implementation of a GPT with billions of parameters that effectively swap text for pixels. Such a model may be trained using text-image pairs from one or more databases. As an example, input to a transformer model may be a sequence of tokenized image captions followed by tokenized image patches. As an example, an image caption may be in a particular language (e.g., a corpus), tokenized by byte pair encoding, for example, up to 256 tokens long. In an example where 256 is given as a limit, each image may be a 256×256 RGB image (e.g., or other color scheme), divided into 32×32 patches of 4×4 each. In such an approach, each patch may then be converted by a discrete variational autoencoder to a token. As an example, CLIP may be utilized as a technique for training a pair of models where one model takes in a piece of text and outputs a single vector and another model takes in an image and outputs a single vector. To train such a pair of models, as an example, a method may include preparing a large dataset of image-caption pairs followed by sampling of batches. For example, consider utilization of GUIs, GUI elements, plots, diagrams, etc., which may include captions, embedded text that may be extracted, etc.

An article by Seneviratne, Senanayake, Rasnayaka, Vidanaarachchi, and Thompson, entitled “DALLE-URBAN: Capturing the urban design expertise of large text to image transformers”, 2022 (10.48550/arXiv.2208.04139) is incorporated by reference herein in its entirety.

As an example, image-text relationships may be established using one or more techniques, which may provide for context-based relationships (e.g., images associated with a particular drilling analysis) and/or GUI configuration settings relationships (e.g., images associated with underlying configuration settings).

As an example, one or more features of one or more of the architectures 710 and 720 may be utilized for a GenAI engine (see, e.g., the GUI 600 of FIG. 6). In such an example, responsive to a prompt, the GenAI engine may return configurations for one or more GUIs. As an example, one or more features of one or more of the architectures 710 and 720 may be utilized for purposes of generation of training data, which may be performed in a supervised, unsupervised and/or semi-supervised manner. As to the term training data, it may include data utilized for training, testing, tuning, etc., as may be performed to generate a trained machine learning model.

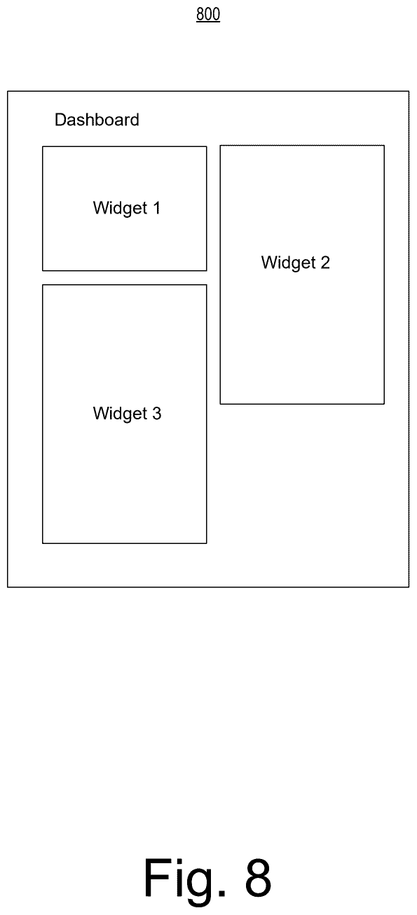

FIG. 8 shows an example of a dashboard 800 with various widgets, which may be associated with executable code, for example, to provide for interactions, renderings, etc. As explained, a widget may be configured for plotting data, whether actual data, simulated data, etc. In the example of FIG. 8, the dashboard includes three widgets in a spatial arrangement, where the widgets may be labeled 1, 2, 3, etc.

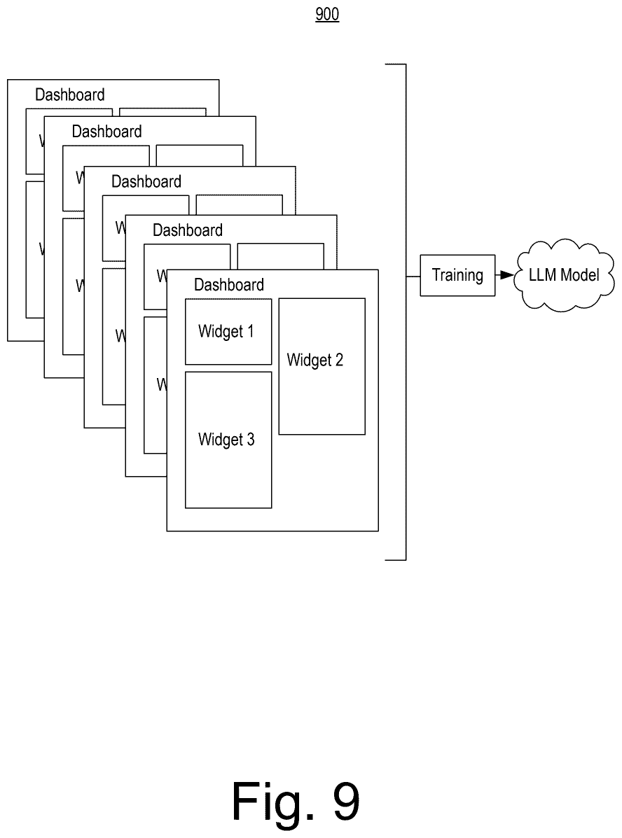

FIG. 9 shows an example of a method 900 for training an LLM. As shown, various dashboards may be provided as training data for training an LLM to generated a trained LLM, which may be part of a GenAI engine. As explained, dashboards may be a source of image content and text content. As an example, dashboards may be subjected to one or more techniques to extract contextual information, which may be provided as or converted to text. For example, consider an approach that extracts colors as to a color scheme, which may be available via parameter settings and/or via color analysis. In such an example, a color scheme may be extracted from imagery and compared to parameter settings, for example, as a quality control measure where, for example, one or more adjustments may be made if appropriate (e.g., harmonizing color labels, specifying parameter values, etc.). As an example, a GenAI engine may include one or more features for override, for example, consider a color scheme override whereby output conforms to a user preferred color scheme rather than an Al generated color scheme.

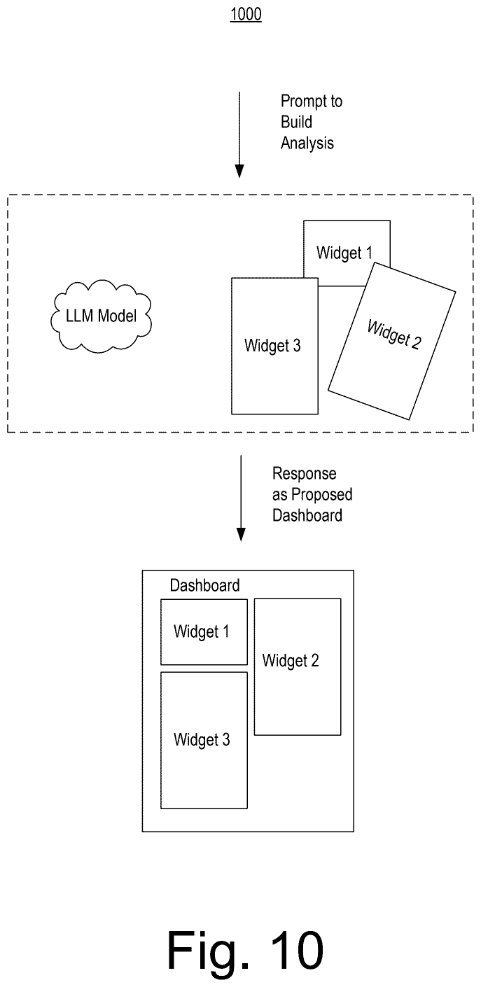

FIG. 10 shows an example of a method 1000 for using a GenAI engine that includes an LLM. As shown, a prompt may be received for building a GUI or GUIs (e.g., for analysis, control, etc.) where, in response to the prompt, a configuration for a GUI or configurations for a series of GUIs may be generated. In such an example, the GUI or GUIs may be rendered to a display or displays. As explained, an analysis may be related to drilling where the GUI or GUIs provide for interactions with one or more frameworks to generate analysis results. As explained, a GUI or GUIs may include one or more features for control of field equipment, for example, consider one or more graphical controls that may be actuated to issue control instructions to control field equipment.

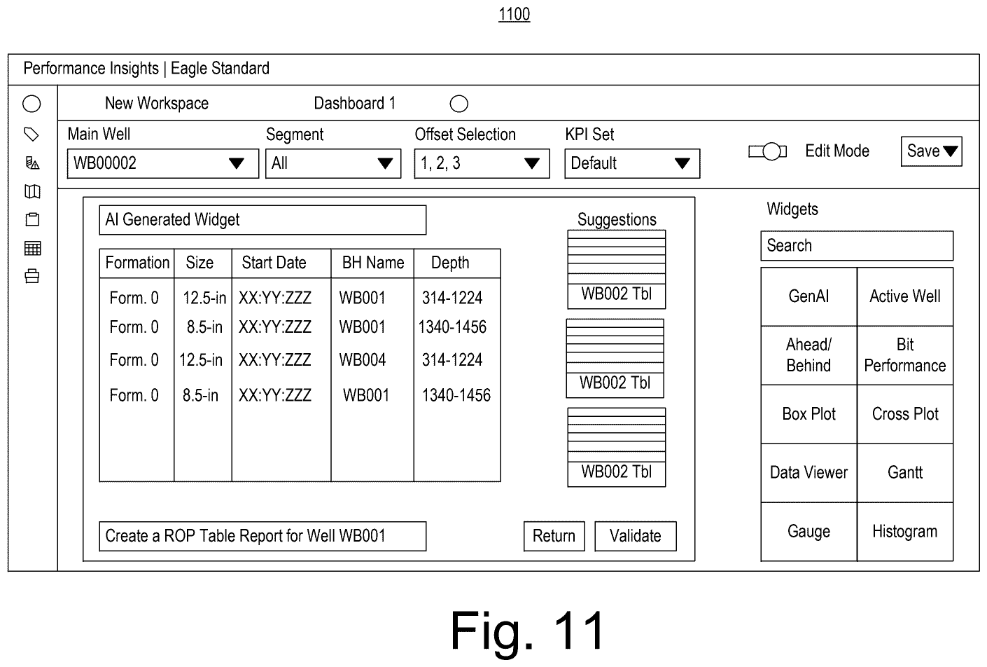

FIG. 11 shows an example of a GUI 1100 that may be rendered to a display upon execution and/or interpretation of instructions by a computing device, which may be a display device that include circuitry that may execute and/or interpret instructions. As shown, the GUI 1100 may include a heading as to a particular type of workflow such as, for example, performance insights. As an example, the GUI 1100 may be rendered as to a method to conduct a performance analysis as to one or more technologies, which may be in a drilling domain, for a well, for a wellbore, for a rig, for a BHA, for drilling fluid (e.g., mud) and/or one or more other technologies related to drilling operations. In various instances, an analysis may focus on one or more issues that may be detrimental, while in other instances, an analysis may focus on one or more successes, for example, to determine what actions resulted in success.

As shown the GUI 1100 may be rendered with a panel that includes suggestions as to one or more configurations (e.g., parameters and/or parameter settings) for the GUI 1100. As an example, the panel may provide for selection of a set of recommended configurations where a graphical control may be rendered for accepting and/or validating a selected set of recommended configurations (e.g., a selected configuration, etc.).

In the example GUI 1100, a right-side panel includes graphics for various widgets, which may be particular applications for performing one or more types of analyses. For example, a GenAI engine itself may be implemented as a widget that when selected provides for configuring one or more GUIs. As shown, widgets may include widgets for an active well, bit performance, cross-plotting Gantt charting, histograms, moving ahead or behind, box-plotting, data viewing, gauge(s), etc. As shown, a search tool may provide for searching a collection of widgets for a particular widget. As an example, the GenAI engine widget may be pinned such that it remains present while other widgets populate the panel.

In the example GUI 1100, various fields are included as to information such as a main well, a segment, offset selection, performance indicator set (e.g., key performance indicator (KPI) set, etc.). As an example, one or more of these fields may be utilized to control and/or configure a GUI or GUIs.

In the example GUI 1100, a field is shown for entering text, which may be utilized as a prompt for submission to a GenAI engine. For example, consider the text “Create a ROP Table Report for Well WB001”. In such an example, a GenAI engine may receive input based on the text to return one or more suggested configurations, which may be based at least in part on learning from one or more previous instances of ROP table report creation for one or more wells (e.g., one or more offset wells, etc.). In the example of FIG. 11, the suggestions may be proposals generated by a GenAI engine responsive to the text, from which a prompt may be formed.

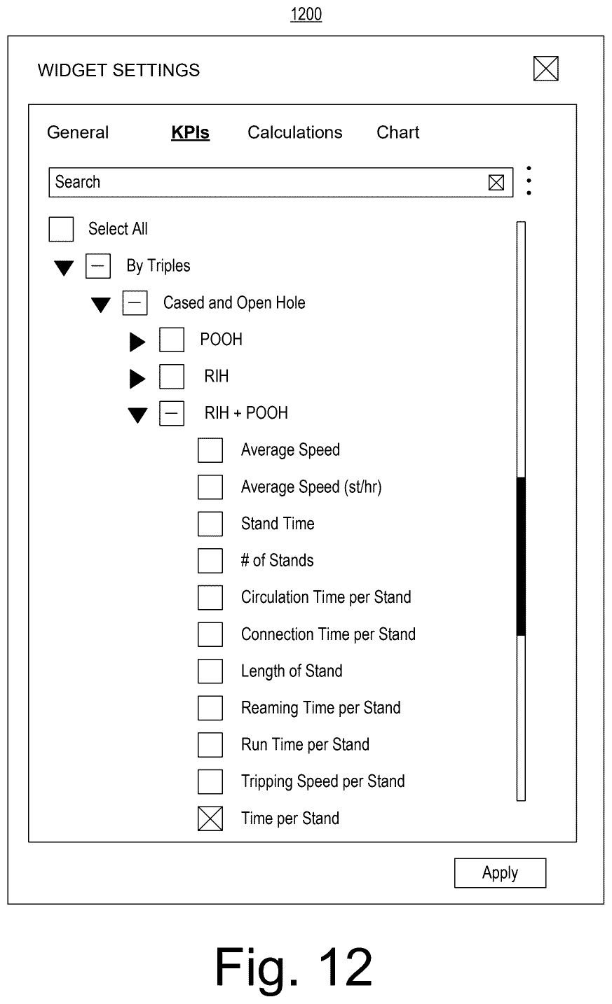

FIG. 12 shows an example of a GUI 1200 with examples of settings where one or more of such settings may be automatically populated responsive to a prompt received by a GenAI engine. For example, a widget may include associated widget settings, which may be categorized in one or more categories. In the example of FIG. 12, the categories include general, KPIs, calculations and chart. As shown, the KPIs category is selected, which includes a hierarchy of settings that may be individually or collectively selected. In the example GUI 1200, under a cased and open hole branch of the hierarchy, an RIH and POOH branch is expanded where a “time per stand” option is selected. Such a selection may provide for configuring performance indicators for an analysis with respect to running-in-hole (RIH) and/or pulling-out-of-hole (POOH) according to time per stand. Specifically, for each stand added or removed from a drillstring, performance indicators will be presented on a time per stand basis (e.g., how much time it takes or took to add a stand to a drillstring during an RIH operation or remove a stand from a drilling string during a POOH operation. As shown, other bases may include average speed in distance per unit time, average speed in stands per unit time, stand time, number of stands, circulation time per stand, connection time per stand, length of stand, reaming time per stand, run time per stand, tripping speed per stand, stand run speed, stationary time per stand, etc.

As explained, prior instances of GUI may be utilized to train one or more machine learning models where, for example, one or more settings may be extracted from data (e.g., metadata as to settings, etc.) and/or directly from an image of a GUI (e.g., optical character recognition of GUI text, shapes, characteristics of graphics, etc.). As an example, an image-based approach may provide for image segmentation and recognition of one or more elements in an image or a portion thereof. For example, a time per stand plot may have labels and/or certain characteristics that distinguish it from an average speed plot and/or one or more other types of plots. In such an example, a trained machine learning model may provide for identification of particular graphics in a manner akin to identification of objects in pictures (e.g., cats, dogs, humans, cars, trucks, signs, lights, etc.).

As an example, a trained machine learning model may provide for automatically extracting context from a screenshot of a GUI to thereby provide for automatic labeling of content within the GUI and/or the GUI overall (e.g., as to a particular type of analysis, etc.). As an example, a workflow may proceed in an unsupervised manner as to images whereby portions thereof may be segmented and then labeled, which may be performed manually, semi-automatically, and/or automatically. For example, consider clustering followed by labeling of clusters, which may be performed using one or more of settings, extracted text, human expertise, etc. As explained, a workflow may involve providing and/or generating image-text relationships (e.g., consider image-text relationships suitable for use in a DALL⋅E model-based approach, etc.).

In various instances, information regarding configuration of a GUI or a portion thereof may be redundant. For example, consider using a settings approach and an image approach. In such an example, accuracy may be enhanced such that configuration(s) output by a GenAI engine may be more robust and reliable. In various instances, output by a GenAI engine may not get a user to a one-hundred percent end result; however, such output may be expected to expedite the user's ability to get to that end result (e.g., consider 50 percent or more towards a desired end result). As explained, a GenAI engine-based framework may expedite a user's ability to perform one or more workflows by configuring one or more GUIs in an automated and/or semi-automated manner, which may provide for configurations that extend beyond the knowledge of the user.

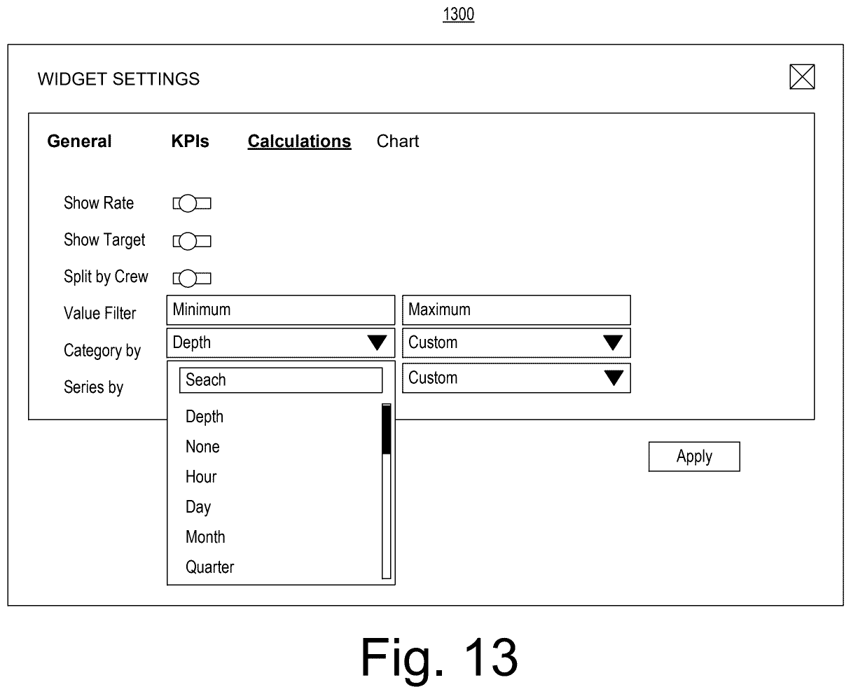

FIG. 13 shows an example of a GUI 1300 that includes various categorized settings (see, e.g., the GUI 1200 of FIG. 12). In the example GUI 1300, the category “calculations” is selected, which provides for rendering of a listing of options (e.g., setting options). As shown, the options may include depth, none, hour, day, month, quarter, etc. In the example GUI 1300, the setting “depth” is selected, which may be selected automatically or semi-automatically from one or more suggestions generated by a GenAI engine. In such an example, a user may expedite an analysis by not having to go through various widget setting to select particular desired settings.

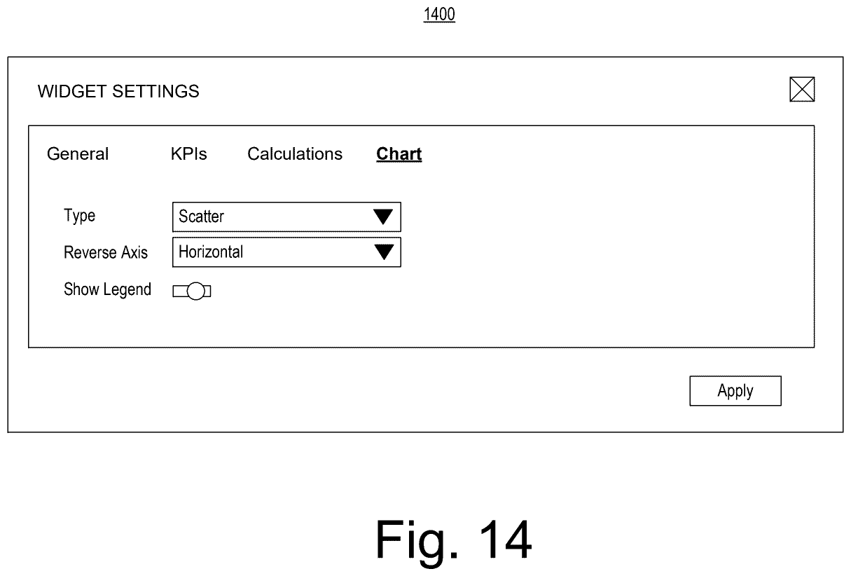

FIG. 14 shows an example of a GUI 1400 that includes various categorized settings (see, e.g., the GUI 1200 of FIG. 12). In the example GUI 1400, the category “chart” is selected, which provides for rendering of a listing of options (e.g., setting options). As shown, the options may include scatter and horizontal. In the example GUI 1400, the setting “horizontal” is selected, which may be selected automatically or semi-automatically from one or more suggestions generated by a GenAI engine. In such an example, a user may expedite an analysis by not having to go through various widget setting to select particular desired settings.

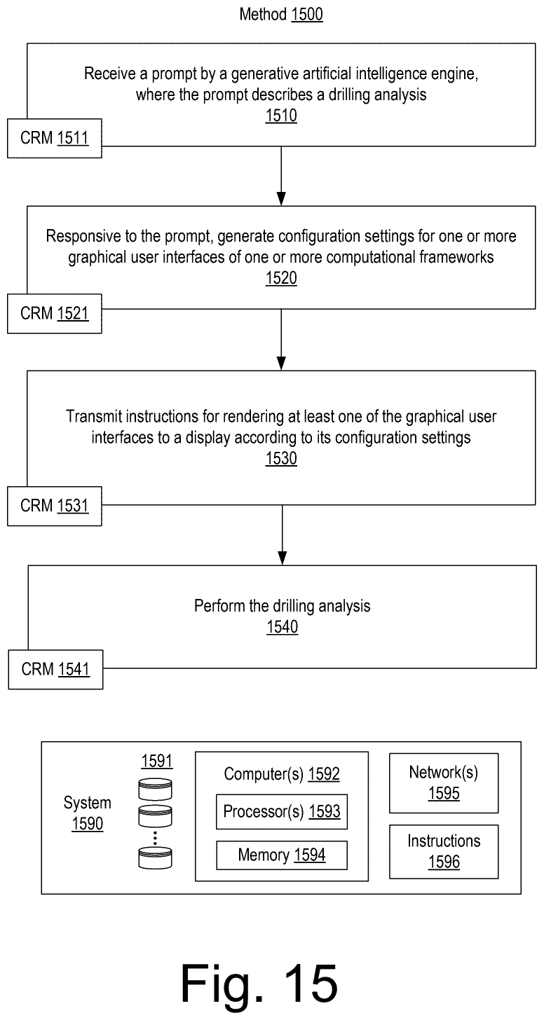

FIG. 15 shows an example of a method 1500 and an example of a system 1590. As shown, the method 1500 may include a reception block 1510 for receiving a prompt by a generative artificial intelligence engine, where the prompt describes a drilling analysis; a generation block 1520 for, responsive to the prompt, generating configuration settings for one or more graphical user interfaces of one or more computational frameworks; and a transmission block 1530 for transmitting instructions for rendering at least one of the graphical user interfaces to a display according to its configuration settings. As shown, the method 1500 may include one or more other blocks such as, for example, a performance block 1540 for performing the drilling analysis.

FIG. 15 also shows various computer-readable media (CRM) blocks 1511, 1521, 1531, and 1541. Such blocks may include instructions that are executable by one or more processors, which may be one or more processors of a computational framework, a system, a computer, etc. A computer-readable medium may be a computer-readable storage medium that is not a signal, not a carrier wave and that is non-transitory. For example, a computer-readable medium may be a physical memory component that may store information in a digital format.

In the example of FIG. 15, a system 1590 includes one or more information storage devices 1591, one or more computers 1592, one or more networks 1595 and instructions 1596. As to the one or more computers 1592, each computer may include one or more processors (e.g., or processing cores) 1593 and memory 1594 for storing the instructions 1596, for example, executable by at least one of the one or more processors. As an example, a computer may include one or more network interfaces (e.g., wired or wireless), one or more graphics cards, a display interface (e.g., wired or wireless), etc. The system 1590 may be specially configured to perform one or more portions of the method 1500 of FIG. 15.

As an example, a computational framework may include a solver, which may be implemented via executable instructions. For example, consider a computational framework that includes a processor and memory accessible to the processor where executable instructions may be stored in the memory and accessed for execution by the processor to cause the computational framework to perform one or more actions. Such a computational framework may include one or more interfaces for receipt of information and/or for output of information, which may include values of parameters, an instruction, etc. As an example, a computational framework may be part of a controller. As an example, a computational framework may be part of a system.

As an example, various systems, methods, etc., may implement one or more ML models. As to types of ML models, consider one or more of a support vector machine (SVM) model, a k-nearest neighbors (KNN) model, an ensemble classifier model, a neural network (NN) model, etc. As an example, a machine learning model may be a deep learning model (e.g., deep Boltzmann machine, deep belief network, convolutional neural network, stacked auto-encoder, etc.), an ensemble model (e.g., random forest, gradient boosting machine, bootstrapped aggregation, AdaBoost, stacked generalization, gradient boosted regression tree, etc.), a neural network model (e.g., radial basis function network, perceptron, back-propagation, Hopfield network, etc.), a regularization model (e.g., ridge regression, least absolute shrinkage and selection operator, elastic net, least angle regression), a rule system model (e.g., cubist, one rule, zero rule, repeated incremental pruning to produce error reduction), a regression model (e.g., linear regression, ordinary least squares regression, stepwise regression, multivariate adaptive regression splines, locally estimated scatterplot smoothing, logistic regression, etc.), a Bayesian model (e.g., naïve Bayes, average on-dependence estimators, Bayesian belief network, Gaussian naïve Bayes, multinomial naïve Bayes, Bayesian network), a decision tree model (e.g., classification and regression tree, iterative dichotomiser 3, C4.5, C5.0, chi-squared automatic interaction detection, decision stump, conditional decision tree, M5), a dimensionality reduction model (e.g., principal component analysis, partial least squares regression, Sammon mapping, multidimensional scaling, projection pursuit, principal component regression, partial least squares discriminant analysis, mixture discriminant analysis, quadratic discriminant analysis, regularized discriminant analysis, flexible discriminant analysis, linear discriminant analysis, etc.), an instance model (e.g., k-nearest neighbor, learning vector quantization, self-organizing map, locally weighted learning, etc.), a clustering model (e.g., k-means, k-medians, expectation maximization, hierarchical clustering, etc.), etc.

As an example, a system may utilize one or more recurrent neural networks (RNNs). One type of RNN is referred to as long short-term memory (LSTM), which may be a unit or component (e.g., of one or more units) that may be in a layer or layers. A LSTM component may be a type of artificial neural network (ANN) designed to recognize patterns in sequences of data, such as time series data. When provided with time series data, LSTMs take time and sequence into account such that an LSTM may include a temporal dimension. For example, consider utilization of one or more RNNs for processing temporal data from one or more sources, optionally in combination with spatial data. Such an approach may recognize temporal patterns, which may be utilized for making predictions (e.g., as to a pattern or patterns for future times, etc.).

As an example, the TENSORFLOW framework (Google LLC, Mountain View, California) may be implemented, which is an open-source software library for dataflow programming that includes a symbolic math library, which may be implemented for machine learning applications that may include neural networks. As an example, the CAFFE framework may be implemented, which is a DL framework developed by Berkeley Al Research (BAIR) (University of California, Berkeley, California). As another example, consider the SCIKIT platform (e.g., scikit-learn), which utilizes the PYTHON programming language. As an example, a framework such as the APOLLO AI framework may be utilized (APOLLO.AI GmbH, Germany). As mentioned, a framework such as the PYTORCH framework may be utilized.

As an example, a training method may include various actions that may operate on a dataset to train a ML model. As an example, a dataset may be split into training data and test data where test data may provide for evaluation. A method may include cross-validation of parameters and best parameters, which may be provided for model training.

The TENSORFLOW framework may run on multiple CPUs and GPUs (with optional CUDA (NVIDIA Corp., Santa Clara, California) and SYCL (The Khronos Group Inc., Beaverton, Oregon) extensions for general-purpose computing on graphics processing units (GPUs)). TENSORFLOW is available on 64-bit LINUX, MACOS (Apple Inc., Cupertino, California), WINDOWS (Microsoft Corp., Redmond, Washington), and mobile computing platforms including ANDROID (Google LLC, Mountain View, California) and IOS (Apple Inc.) operating system-based platforms.

TENSORFLOW computations may be expressed as stateful dataflow graphs; noting that the name TENSORFLOW derives from the operations that such neural networks perform on multidimensional data arrays. Such arrays may be referred to as “tensors”.

As an example, a method may include receiving a prompt by a generative artificial intelligence engine, where the prompt describes a drilling analysis; responsive to the prompt, generating configuration settings for one or more graphical user interfaces of one or more computational frameworks; and transmitting instructions for rendering at least one of the graphical user interfaces to a display according to its configuration settings. In such an example, the prompt may describe a wellbore and/or may describe a section of a wellbore. As an example, a drilling analysis may be for one or more detrimental events and/or for one or more beneficial events. As an example, a beneficial event may be an event associated with successful achievement of one or more goals. For example, consider an ROP goal, a goal of reducing risk of a detrimental event, a time-based goal (e.g., reduced NPT, etc.), etc.

As an example, a detrimental event may be one or more of a stuck pipe event, a kick event, and a lost circulation event. In various instances, events may be related. For example, a lost circulation event may increase risk of a stuck pipe event and/or a kick event. As mentioned, a drilling analysis may be for analysis of a beneficial event.

As an example, a drilling analysis may be for one or more of a drilling operation, a well, a wellbore, a rig, a bottom hole assembly, and drilling fluid.

As an example, a method may include training a generative artificial intelligence engine. For example, consider training that includes using historical configuration settings for graphical user interfaces associated with one or more types of drilling analyses. In such an example, the historical configuration settings may include one or more of size settings, color settings, plot settings, arrangement of elements settings, and sequence settings. As an example, training may include using images. For example, consider using images that include images of GUIs. In such an example, a method may include extracting configuration settings from the images. As explained, plots may include text labels and/or shapes of plotted data (e.g., bars, lines, circles, curves, etc.), which may be associated with particular types of plots that may be amongst plot types for a GUI that may be specified via configuration settings.

As an example, a generative artificial intelligence engine may generate one or more images where a generating process may extract at least a portion of configuration settings from the one or more images. For example, consider a GenAI engine that may generate an image representative of a GUI responsive to receipt of a prompt whereby the image may be subjected to OCR and/or one or more other processes to extract particular configuration settings therefrom. As an example, a GenAI engine may generate an image and associated metadata for the image where such metadata may include configuration settings for one or more features of the image (e.g., one or more widget panels, etc.).

As an example, a generative artificial intelligence engine may include a large language model. As an example, a generative artificial intelligence engine may include a trained machine learning model. As an example, a generative artificial intelligence engine may include a large language model and one or more trained machine learning models. As an example, output of a large language model may be utilized to drive one or more trained machine learning models. For example, consider an architecture with an LLM front-end that may respond to a prompt by generating particular text whereby a trained machine learning model may operate using such text as input to generate one or more images and/or data descriptive of one or more images, which may be GUI or GUI element images whereby such data may be configuration settings data, include configuration settings data, provide for deriving configuration settings data, etc.

As an example, a system may include one or more processors; memory accessible to at least one of the one or more processors; processor-executable instructions stored in the memory and executable to instruct the system to: receive a prompt by a generative artificial intelligence engine, where the prompt describes a drilling analysis; responsive to the prompt, generate configuration settings for one or more graphical user interfaces of one or more computational frameworks; and transmit instructions for rendering at least one of the graphical user interfaces to a display according to its configuration settings.

As an example, one or more computer-readable storage media may include processor-executable instructions to instruct a computing system to: receive a prompt by a generative artificial intelligence engine, where the prompt describes a drilling analysis; responsive to the prompt, generate configuration settings for one or more graphical user interfaces of one or more computational frameworks; and transmit instructions for rendering at least one of the graphical user interfaces to a display according to its configuration settings.

As an example, a computer program product that may include computer-executable instructions to instruct a computing system to perform one or more methods such as one or more of the methods described herein (e.g., in part, in whole and/or in various combinations).

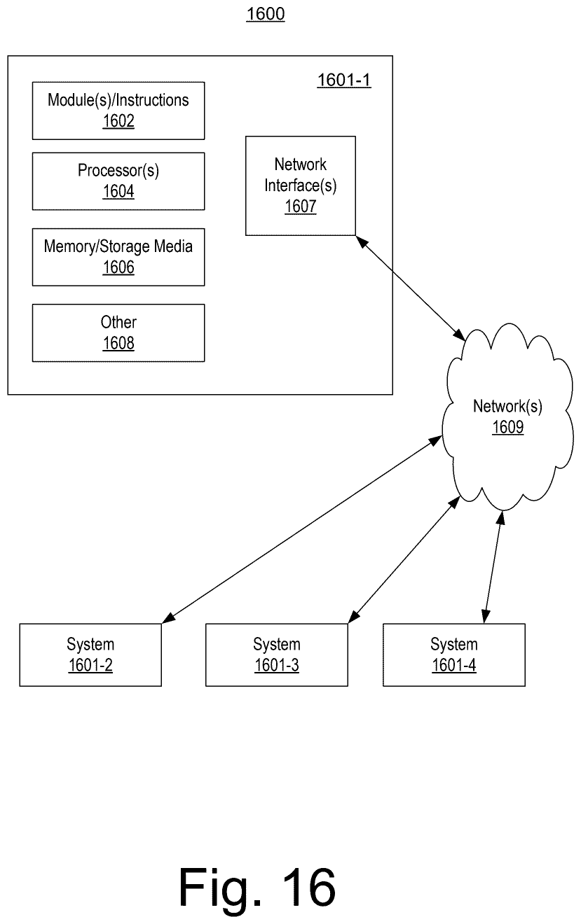

In some embodiments, a method or methods may be executed by a computing system. FIG. 16 shows an example of a system 1600 that may include one or more computing systems 1601-1, 1601-2, 1601-3 and 1601-4, which may be operatively coupled via one or more networks 1609, which may include wired and/or wireless networks. As shown, the system 1600 may include one or more other components 1608.

As an example, a system may include an individual computer system or an arrangement of distributed computer systems. In the example of FIG. 16, the computer system 1601-1 may include one or more modules 1602, which may be or include processor-executable instructions, for example, executable to perform various tasks (e.g., receiving information, requesting information, processing information, simulation, outputting information, etc.).

As an example, a module may be executed independently, or in coordination with, one or more processors 1604, which is (or are) operatively coupled to one or more storage media 1606 (e.g., via wire, wirelessly, etc.). As an example, one or more of the one or more processors 1604 may be operatively coupled to at least one of one or more network interface 1607. In such an example, the computer system 1601-1 may transmit and/or receive information, for example, via the one or more networks 1609 (e.g., consider one or more of the Internet, a private network, a cellular network, a satellite network, etc.). As shown, one or more other components 1608 may be included in the computer system 1601-1.

As an example, the computer system 1601-1 may receive from and/or transmit information to one or more other devices, which may be or include, for example, one or more of the computer systems 1601-2, etc. A device may be located in a physical location that differs from that of the computer system 1601-1. As an example, a location may be, for example, a processing facility location, a data center location (e.g., server farm, etc.), a rig location, a wellsite location, a downhole location, etc.

As an example, a processor may be or include a microprocessor, microcontroller, processor module or subsystem, programmable integrated circuit, programmable gate array, or another control or computing device.

As an example, the storage media 1606 may be implemented as one or more computer-readable or machine-readable storage media. As an example, storage may be distributed within and/or across multiple internal and/or external enclosures of a computing system and/or additional computing systems.

As an example, a storage medium or storage media may include one or more different forms of memory including semiconductor memory devices such as dynamic or static random access memories (DRAMs or SRAMs), erasable and programmable read-only memories (EPROMs), electrically erasable and programmable read-only memories (EEPROMs) and flash memories, magnetic disks such as fixed, floppy and removable disks, other magnetic media including tape, optical media such as compact disks (CDs) or digital video disks (DVDs), BLUERAY disks, or other types of optical storage, or other types of storage devices.

As an example, a storage medium or media may be located in a machine running machine-readable instructions, or located at a remote site from which machine-readable instructions may be downloaded over a network for execution.

As an example, various components of a system such as, for example, a computer system, may be implemented in hardware, software, or a combination of both hardware and software (e.g., including firmware), including one or more signal processing and/or application specific integrated circuits.

As an example, a system may include a processing apparatus that may be or include a general-purpose processors or application specific chips (e.g., or chipsets), such as ASICs, FPGAs, PLDs, or other appropriate devices.

As an example, a device may be a mobile device that includes one or more network interfaces for communication of information. For example, a mobile device may include a wireless network interface (e.g., operable via IEEE 802.11, ETSI GSM, BLUETOOTH, satellite, etc.). As an example, a mobile device may include components such as a main processor, memory, a display, display graphics circuitry (e.g., optionally including touch and gesture circuitry), a SIM slot, audio/video circuitry, motion processing circuitry (e.g., accelerometer, gyroscope), wireless LAN circuitry, smart card circuitry, transmitter circuitry, GPS circuitry, and a battery. As an example, a mobile device may be configured as a cell phone, a tablet, etc. As an example, a method may be implemented (e.g., wholly or in part) using a mobile device. As an example, a system may include one or more mobile devices.

As an example, a system may be a distributed environment, for example, a so-called “cloud” environment where various devices, components, etc. interact for purposes of data storage, communications, computing, etc. As an example, a device or a system may include one or more components for communication of information via one or more of the Internet (e.g., where communication occurs via one or more Internet protocols), a cellular network, a satellite network, etc. As an example, a method may be implemented in a distributed environment (e.g., wholly or in part as a cloud-based service).

As an example, information may be input from a display (e.g., consider a touchscreen), output to a display or both. As an example, information may be output to a projector, a laser device, a printer, etc. such that the information may be viewed. As an example, information may be output stereographically or holographically. As to a printer, consider a 2D or a 3D printer. As an example, a 3D printer may include one or more substances that may be output to construct a 3D object. For example, data may be provided to a 3D printer to construct a 3D representation of a subterranean formation. As an example, layers may be constructed in 3D (e.g., horizons, etc.), geobodies constructed in 3D, etc. As an example, holes, fractures, etc., may be constructed in 3D (e.g., as positive structures, as negative structures, etc.).

Although only a few examples have been described in detail above, those skilled in the art will readily appreciate that many modifications are possible in the examples. Accordingly, all such modifications are intended to be included within the scope of this disclosure as defined in the following claims. In the claims, means-plus-function clauses are intended to cover the structures described herein as performing the recited function and not only structural equivalents, but also equivalent structures. Thus, although a nail and a screw may not be structural equivalents in that a nail employs a cylindrical surface to secure wooden parts together, whereas a screw employs a helical surface, in the environment of fastening wooden parts, a nail and a screw may be equivalent structures.

What is claimed is:

1. A method comprising:
receiving a prompt by a generative artificial intelligence engine, wherein the prompt describes a drilling analysis;
responsive to the prompt, generating configuration settings for one or more graphical user interfaces of one or more computational frameworks; and
transmitting instructions for rendering at least one of the graphical user interfaces to a display according to its configuration settings.

2. The method of claim 1, wherein the prompt describes a wellbore.

3. The method of claim 1, wherein the prompt describes a section of a wellbore.

4. The method of claim 1, wherein the drilling analysis is for analysis of a detrimental event.

5. The method of claim 4, wherein the detrimental event is one or more of a stuck pipe event, a kick event, and a lost circulation event.

6. The method of claim 1, wherein the drilling analysis is for analysis of a beneficial event.

7. The method of claim 1, wherein the drilling analysis is for one or more of a drilling operation, a well, a wellbore, a rig, a bottom hole assembly, and drilling fluid.

8. The method of claim 1, comprising training the generative artificial intelligence engine.

9. The method of claim 8, wherein the training comprises using historical configuration settings for graphical user interfaces associated with one or more types of drilling analyses.

10. The method of claim 9, wherein the historical configuration settings comprise one or more of size settings, color settings, plot settings, arrangement of elements settings, and sequence settings.

11. The method of claim 8, wherein the training comprises using images.

12. The method of claim 11, wherein the images comprise images of GUIs.

13. The method of claim 11, comprising extracting configuration settings from the images.

14. The method of claim 1, wherein the generative artificial intelligence engine generates one or more images and wherein the generating extracts at least a portion of the configuration settings from the one or more images.

15. The method of claim 1, wherein the generative artificial intelligence engine comprises a large language model.

16. The method of claim 1, wherein the generative artificial intelligence engine comprises a trained machine learning model.

17. The method of claim 1, wherein the generative artificial intelligence engine comprises a large language model and one or more trained machine learning models.

18. The method of claim 17, wherein output of the large language model drives the one or more trained machine learning models.

19. A system comprising:
one or more processors;
memory accessible to at least one of the one or more processors;
processor-executable instructions stored in the memory and executable to instruct the system to:
receive a prompt by a generative artificial intelligence engine, wherein the prompt describes a drilling analysis;
responsive to the prompt, generate configuration settings for one or more graphical user interfaces of one or more computational frameworks; and
transmit instructions for rendering at least one of the graphical user interfaces to a display according to its configuration settings.

20. One or more computer-readable storage media comprising processor-executable instructions to instruct a computing system to:
receive a prompt by a generative artificial intelligence engine, wherein the prompt describes a drilling analysis;
responsive to the prompt, generate configuration settings for one or more graphical user interfaces of one or more computational frameworks; and
transmit instructions for rendering at least one of the graphical user interfaces to a display according to its configuration settings.
